(19) United States
(12) Patent Application Publication
(10) Pub. No.: US 2022/0302408 A1
(43) Pub. Date: Sep. 22, 2022

(54) LIGHT TRANSMISSIVE ELECTRODE FOR LIGHT EMITTING DEVICES

(71) Applicant: OTI LUMIONICS INC., Mississauga (CA)

(72) Inventors: Yi-Lu CHANG, Scarborough (CA); Qi WANG, North York (CA); Zhibin WANG, Toronto (CA); Michael HELANDER, Toronto (CA)

(73) Assignee: OTI LUMIONICS INC., Mississauga, ON (CA)

(21) Appl. No.: 17/638,162

(22) PCT Filed: Aug. 27, 2020
(86) PCT No.: PCT/IB2020/057993

§ 371 Date: Feb. 24, 2022

Related U.S. Application Data
(60) Provisional application No. 62/892,437, filed on Aug. 27, 2019.
(60) Provisional application No. 62/897,894, filed on Sep. 9, 2019.

(51) Int. Cl. H01L 51/52; H01L 51/00

(52) U.S. Cl. CPC H01L 51/5234; H01L 51/0046; H01L 51/5215

(57) ABSTRACT

An opto-electronic device comprises first and second electrodes and a semiconducting layer therebetween. The second electrode comprises ytterbium and magnesium. The second electrode may comprise a fullerene. The second electrode may comprise a lower section comprising ytterbium and/or fullerene and an upper section comprising a ytterbium-containing magnesium alloy. The lower section may comprise an interface section in physical contact with the semiconducting layer. The interface section may comprise ytterbium fulleride. In some examples, an interface coating comprising ytterbium extends across a pixel region and a transmissive region. A nucleation inhibiting coating (NIC) is disposed over the interface coating in the transmissive region. A conductive coating is disposed over the interface coating in the pixel region. The NIC surface in the transmissive region is substantially devoid of a closed coating film of the conductive coating. The interface coating may comprise fullerene. The conductive coating may be a ytterbium-containing magnesium alloy.

### RELATED APPLICATIONS

The present application claims the benefit of priority to each of U.S. Provisional Patent Application No. 62/892,437, filed 27 Aug. 2019 and U.S. Provisional Patent Application No. 62/897,894, filed 9 Sep. 2019, the contents of each of which are incorporated herein by reference in their entirety.

### TECHNICAL FIELD

The present disclosure relates to opto-electronic devices and in particular to an opto-electronic device having first and second electrodes separated by a semiconductor layer.

### BACKGROUND

In an opto-electronic device such as an organic light emitting diode (OLED), at least one semiconducting layer is disposed between a pair of electrodes, such as an anode and a cathode. The anode and cathode are electrically coupled to a power source and respectively generate holes and electrons that migrate toward each other through the at least one semiconducting layer. When a pair of holes and electrons combine, a photon may be emitted.

OLED display panels may comprise a plurality of (sub-) pixels, each of which has an associated pair of electrodes. Various layers and coatings of such panels are typically formed by vacuum-based deposition techniques.

In some applications, it may be desirable to provide a conductive coating in a pattern for each (sub-) pixel of the panel across either or both of a lateral and a cross-sectional aspect thereof, by selective deposition of the conductive coating to form a device feature, such as, without limitation, an electrode and/or a conductive element electrically coupled thereto, during the OLED manufacturing process.

One method for doing so, especially when the electrode is a light transmissive electrode, involves depositing, by a sputtering process, materials typically used to form the transmissive electrode, including transparent conducting oxides (TCOs), such as, without limitation, indium tin oxide (ITO) and/or zinc oxide (ZnO). In a sputtering process, a target is bombarded to produce sputtered atoms that then travel to the desired surface to be deposited thereon. However, since sputtered atoms generally possess a high kinetic energy, there is a relatively high likelihood of any organic and/or inorganic semiconductor layers formed on the surface becoming damaged during the sputtering process. Accordingly, sputtered films are generally undesirable for use as an electrode, particularly in cases where such electrode is to be disposed directly over sensitive organic semiconductor layers.

In some non-limiting examples, thin films, such as those formed by depositing a thin layer of silver (Ag), aluminum (Al), and/or various metallic alloys, such as, without limitation, a magnesium silver (Mg:Ag) alloy and/or a ytterbium silver (Yb:Ag) alloy, with compositions ranging from about 1:9 to 9:1 by volume may also be used to form a transmissive electrode. However, the use of materials such as Ag and/or Al specify such materials to be deposited by thermal evaporation at high temperatures in excess of 1000° C., which can cause degradation and/or damage to the substrate and/or the organic semiconductor layers upon which such material is deposited.

In some non-limiting examples, a multi-layered electrode including two or more layers of TCOs and/or thin metal films may be used. However, these materials generally provide a relatively poor trade-off between light transmission and resistivity. Further, two or more separate deposition steps are generally performed to achieve such construction. Since each additional deposition step that is introduced into a production process generally increases cost and may introduce additional defects and may consequently result in lower yields, it may be difficult to incorporate such multi-layered electrodes into a device structure.

One method for doing so, in some non-limiting applications, involves the interposition of a fine metal mask (FMM) during deposition of an electrode material and/or a conductive element electrically coupled thereto. However, materials typically used as electrodes have relatively high evaporation temperatures, which impacts the ability to re-use the FMM and/or the accuracy of the pattern that may be achieved, with attendant increases in cost, effort and complexity.

One method for doing so, in some non-limiting examples, involves depositing the electrode material and thereafter removing, including by a laser drilling process, unwanted regions thereof to form the pattern. However, the removal process often involves the creation and/or presence of debris, which may affect the yield of the manufacturing process.

Further, such methods may not be suitable for use in some applications and/or with some devices with certain topographical features.

It would be beneficial to provide an improved mechanism for providing selective deposition of a conductive coating.

### BRIEF DESCRIPTION OF THE DRAWINGS

Examples of the present disclosure will now be described by reference to the following figures, in which identical reference numerals in different figures indicate identical and/or in some non-limiting examples, analogous and/or corresponding elements and in which:

FIG. 1 is a block diagram from a cross-sectional aspect, of an example electro-luminescent device according to an example in the present disclosure;

FIG. 2 is a cross-sectional view of the device of FIG. 1;

FIG. 3 is an example energy profile illustrating relative energy states of an adatom absorbed onto a surface according to an example in the present disclosure;

FIG. 4 is a schematic diagram showing an example process for depositing a selective coating in a pattern on an exposed layer surface of an underlying material in an example version of the device of FIG. 1, according to an example in the present disclosure;

FIG. 5 is a schematic diagram showing an example process for depositing a conductive coating in the first pattern on an exposed layer surface that comprises the deposited pattern of the selective coating of FIG. 7 where the selective coating is a nucleation-inhibiting coating (NIC);

FIG. 6 is an example version of the device of FIG. 1, with additional example deposition steps according to an example in the present disclosure;

FIG. 7A is an example version of the device of FIG. 1, having a lower section and an upper section, according to an example in the present disclosure;

FIG. 7B is an example version of the device of FIG. 7A, in which the lower section comprises an interface section and/or an intermediate section, according to an example in the present disclosure;

FIG. 7C is an example version of the device of FIG. 7A, in which the second electrode is in physical contact with an electron transport layer, according to an example in the present disclosure;

FIG. 8 is a schematic diagram illustrating, in plan view, an example of a transparent version of the device of FIG. 1 comprising at least one example pixel region and at least one example light-transmissive region, with at least one auxiliary electrode according to an example in the present disclosure; and

FIG. 9 is a schematic diagram illustrating an example cross-sectional view of the device of FIG. 8 taken along line 26B-26B, according to an example in the present disclosure.

In the present disclosure, for purposes of explanation and not limitation, specific details are set forth in order to provide a thorough understanding of the present disclosure, including, without limitation, particular architectures, interfaces and/or techniques. In some instances, detailed descriptions of well-known systems, technologies, components, devices, circuits, methods and applications are omitted so as not to obscure the description of the present disclosure with unnecessary detail.

Further, it will be appreciated that block diagrams reproduced herein can represent conceptual views of illustrative components embodying the principles of the technology.

Accordingly, the system and method components have been represented where appropriate by conventional symbols in the drawings, showing only those specific details that are pertinent to understanding the examples of the present disclosure, so as not to obscure the disclosure with details that will be readily apparent to those of ordinary skill in the art having the benefit of the description herein.

Any drawings provided herein may not be drawn to scale and may not be considered to limit the present disclosure in any way.

Any feature or action shown in dashed outline may in some examples be considered as optional.

### SUMMARY

It is an object of the present disclosure to obviate or mitigate at least one disadvantage of the prior art.

The present disclosure discloses an opto-electronic device comprises first and second electrodes and a semiconducting layer therebetween. The second electrode comprises Yb and Mg. The second electrode may comprise a fullerene. The second electrode may comprise a lower section comprising Yb and/or fullerene and an upper section comprising a Yb-containing Mg alloy. The lower section may comprise an interface section in physical contact with the semiconducting layer. The interface section may comprise ytterbium fulleride. In some examples, an interface coating comprising Yb extends across a pixel region and a transmissive region. An NIC is disposed over the interface coating in the transmissive region. A conductive coating is disposed over the interface coating in the pixel region. The NIC surface in the transmissive region is substantially devoid of a closed coating film of the conductive coating. The interface coating may comprise fullerene. The conductive coating may be a Yb-containing Mg alloy.

According to a broad aspect of the present disclosure, there is disclosed an opto-electronic device having a plurality of layers, comprising: a first electrode; a second electrode; and at least one semiconducting layer between the first and second electrodes; wherein the second electrode comprises ytterbium (Yb) and magnesium (Mg).

In some non-limiting examples, a concentration of the Yb in the second electrode may comprise a non-zero amount of up to 35 vol. %.

In some non-limiting examples, a thickness of the second electrode is between about 6 nm and about 35 nm.

In some non-limiting examples, the second electrode may comprise a lower section and an upper section, wherein the lower section is between the upper section and the at least one semiconducting layer and proximate to the at least one semiconducting layer. In some non-limiting examples, the lower section may be substantially comprised of Yb. In some non-limiting examples, the upper section may comprise a Yb-containing Mg alloy wherein a concentration of the Yb therein comprises a non-zero amount of up to 10 vol. % of the upper section. In some non-limiting examples, a concentration of the Yb in the lower section may exceed a concentration of the Yb in the upper section.

In some non-limiting examples, a thickness of the lower section may be between about 1 nm and about 5 nm. In some non-limiting examples, a thickness of the upper section may be between about 5 nm and about 30 nm.

In some non-limiting examples, the upper section may be substantially devoid of Yb. In some non-limiting examples, the upper section may be comprised substantially of Mg.

In some non-limiting examples, the second electrode may further comprise a fullerene. In some non-limiting examples, a concentration of the fullerene in the second electrode may comprise a non-zero amount of up to 15 vol. %.

In some non-limiting examples, the second electrode may comprise a lower section and an upper section, wherein the lower section is between the upper section and the at least one semiconducting layer and proximate to the at least one semiconducting layer. In some non-limiting examples, a concentration of fullerene in the lower section may exceed a concentration of the fullerene in the upper section. In some non-limiting examples, the upper section may be substantially devoid of the fullerene.

In some non-limiting examples, the lower section may further comprise an interface section arranged to be in physical contact with the at least one semiconducting layer. In some non-limiting examples, a thickness of the interface section may be between about 1 nm and about 5 nm. In some non-limiting examples, the interface section may further comprise Mg. In some non-limiting examples, the interface section may comprise ytterbium fulleride. In some non-limiting examples, a chemical state of Yb in the interface section may comprise at least one of Yb²⁺ and Yb³⁺. In some non-limiting examples, the ytterbium fulleride in the interface section may have a chemical formula YbₓC_{y}, wherein 2≤x≤3 and 50≤y≤84. In some non-limiting examples, the fullerene may comprise at least one of Cₙ, where 50≤n≤250. In some non-limiting examples, n may be selected from at least one of 60, 70, 72, 75, 76, 78, 80, 82, 84 and any combination of any of these.

According to a broad aspect of the present disclosure, there is disclosed an opto-electronic device having a plurality of layers, comprising: a pixel region in a first portion of a lateral aspect thereof; a light transmissive region in a second portion of a lateral aspect thereof; a first electrode disposed in the pixel region; an interface coating extending across the pixel region and the light transmissive region, the interface coating comprising ytterbium (Yb); at least one semiconducting layer between the first electrode and the interface coating; a nucleation inhibiting coating (NIC) disposed over the interface coating in the light transmissive region; and a conductive coating disposed over the interface coating in the pixel region; wherein a surface of the NIC in the light transmissive region is substantially devoid of a closed coating film of the conductive coating.

In some non-limiting examples, the interface coating may be in physical contact with the at least one semiconducting layer in the pixel region. In some non-limiting examples, the interface coating may be in physical contact with the conductive coating in the pixel region. In some non-limiting examples, the interface coating may be in physical contact with the NIC in the light transmissive region.

In some non-limiting examples, the device may further comprise a second electrode in the pixel region comprising the interface coating and the conductive coating.

In some non-limiting examples, the interface coating may further comprise a fullerene. In some non-limiting examples, the fullerene may comprise at least one of Cₙ, where 50≤n≤250. In some non-limiting examples, n may be selected from at least one of 60, 70, 72, 75, 76, 78, 80, 82, 84 and any combination of any of these.

In some non-limiting examples, a discontinuous coating of a material for forming the conductive coating may be arranged on a surface of the NIC in the transmissive region. In some non-limiting examples, light transmitted through the transmissive region may pass substantially through the discontinuous coating. In some non-limiting examples, a thickness of the material for forming the conductive coating on the surface of the NIC may be less than about 10% of a thickness of the conductive coating in the pixel region.

According to a broad aspect of the present disclosure, there is disclosed an opto-electronic device having a plurality of layers, comprising: a pixel region in a first portion of a lateral aspect thereof; a light transmissive region in a second portion of a lateral aspect thereof; a first electrode disposed in the pixel region; at least one semiconducting layer disposed over the first electrode; a nucleation inhibiting coating (NIC) disposed over the at least one semiconducting layer in the light transmissive region; and a conductive coating disposed over the at least one semiconducting layer in the pixel region, the conductive coating comprising a ytterbium- (Yb-) containing magnesium (Mg) alloy wherein a concentration of the Yb therein comprises a non-zero amount of up to 15 vol. % of the conductive coating; wherein a surface of the NIC in the light transmissive region is substantially devoid of a closed coating film of the conductive coating.

### DESCRIPTION

### Opto-Electronic Device

The present disclosure relates generally to electronic devices, and more specifically, to opto-electronic devices. An opto-electronic device generally encompasses any device that converts electrical signals into photons and vice versa.

In the present disclosure, the terms “photon” and “light” may be used interchangeably to refer to similar concepts. In the present disclosure, photons may have a wavelength that lies in the visible light spectrum, in the infrared (IR) and/or ultraviolet (UV) region thereof.

In the present disclosure, the term “visible light spectrum” as used herein, generally refers to at least one wavelength in the visible portion of the electromagnetic spectrum. As would be appreciated by those having ordinary skill in the relevant art, such visible portion may correspond to any wavelength from about 380 nm to about 740 nm. In general, electro-luminescent devices are configured to emit and/or transmit light having wavelengths in a range from about 425 nm to about 725 nm, and more specifically, in some non-limiting examples, light having peak emission wavelengths of 456 nm, 528 nm, and 624 nm, corresponding to B(lue), G(reen), and R(ed), respectively. Accordingly, in the context of such electro-luminescent devices, the visible portion may refer to any wavelength from about 425 nm to about 725 nm, or from about 456 nm to about 624 nm.

An organic opto-electronic device can encompass any opto-electronic device where one or more active layers and/or strata thereof are formed primarily of an organic (carbon-containing) material, and more specifically, an organic semiconductor material.

In the present disclosure, it will be appreciated by those having ordinary skill in the relevant art that an organic material, may comprise, without limitation, a wide variety of organic molecules, and/or organic polymers. Further, it will be appreciated by those having ordinary skill in the relevant art that organic materials that are doped with various inorganic substances, including without limitation, elements and/or inorganic compounds, may still be considered to be organic materials. Still further, it will be appreciated by those having ordinary skill in the relevant art that various organic materials may be used, and that the processes described herein are generally applicable to an entire range of such organic materials.

In the present disclosure, an inorganic substance may refer to a substance that primarily includes an inorganic material. In the present disclosure, an inorganic material may comprise any material that is not considered to be an organic material, including without limitation, metals, glasses and/or minerals.

Where the opto-electronic device emits photons through a luminescent process, the device may be considered an electro-luminescent device. In some non-limiting examples, the electro-luminescent device may be an organic light-emitting diode (OLED) device. In some non-limiting examples, the electro-luminescent device may be part of an electronic device. By way of non-limiting example, the electro-luminescent device may be an OLED lighting panel or module, and/or an OLED display or module of a computing device, such as a smartphone, a tablet, a laptop, an e-reader, and/or of some other electronic device such as a monitor and/or a television set.

In some non-limiting examples, the opto-electronic device may be an organic photo-voltaic (OPV) device that converts photons into electricity. In some non-limiting examples, the opto-electronic device may be an electro-luminescent quantum dot device. In the present disclosure, unless specifically indicated to the contrary, reference will be made to OLED devices, with the understanding that such disclosure could, in some examples, equally be made applicable to other opto-electronic devices, including without limitation, an OPV and/or quantum dot device in a manner apparent to those having ordinary skill in the relevant art.

The structure of such devices will be described from each of two aspects, namely from a cross-sectional aspect and/or from a lateral (plan view) aspect.

In the present disclosure, the terms “layer” and “strata” may be used interchangeably to refer to similar concepts.

In the context of introducing the cross-sectional aspect below, the components of such devices are shown in substantially planar lateral strata. Those having ordinary skill in the relevant art will appreciate that such substantially planar representation is for purposes of illustration only, and that across a lateral extent of such a device, there may be localized substantially planar strata of different thicknesses and dimension, including, in some non-limiting examples, the substantially complete absence of a layer, and/or layer(s) separated by non-planar transition regions (including lateral gaps and even discontinuities). Thus, while for illustrative purposes, the device is shown below in its cross-sectional aspect as a substantially stratified structure, in the plan view aspect discussed below, such device may illustrate a diverse topography to define features, each of which may substantially exhibit the stratified profile discussed in the cross-sectional aspect.

### Cross-Sectional Aspect

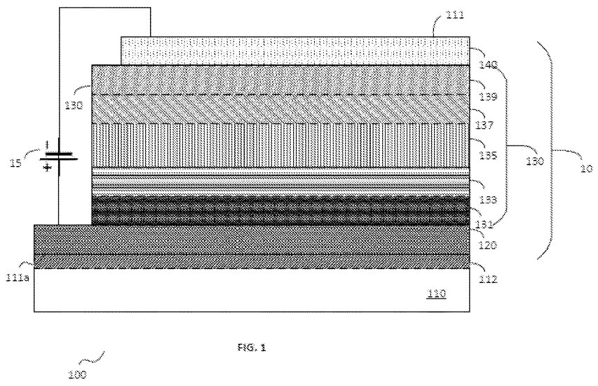

FIG. 1 is a simplified block diagram from a cross-sectional aspect, of an example electro-luminescent device according to the present disclosure. The electro-luminescent device, shown generally at 100 comprises, a substrate 110, upon which a frontplane 10, comprising a plurality of layers, respectively, a first electrode 120, at least one semiconducting layer 130, and a second electrode 140, are disposed. In some non-limiting examples, the frontplane 10 may provide mechanisms for photon emission and/or manipulation of emitted photons.

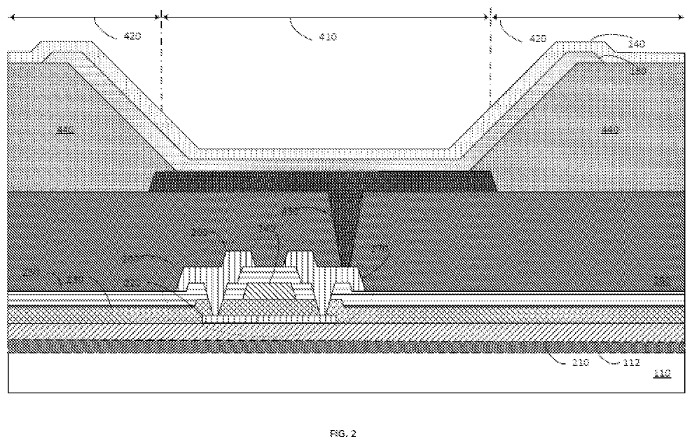

In some non-limiting examples, various layers and/or parts of a frontplane 10, including without limitation, the first electrode 120, the at least one semiconducting layer 130, the second electrode 140, a pixel definition layer (PDL) 440 (FIG. 2) and/or a capping layer, may be deposited by any of the various deposition methodologies described herein, including without limitation, by a thermal evaporation method, and/or with or without masks. For purposes of illustration, an exposed layer surface of underlying material is referred to as 111. In FIG. 1, the exposed layer surface 111 is shown as being of the second electrode 140. Those having ordinary skill in the relevant art will appreciate that, at the time of deposition of, by way of non-limiting example, the first electrode 120, the exposed layer surface 111 would have been shown as 111a, of the substrate 110.

Those having ordinary skill in the relevant art will appreciate that when a component, a layer, a region and/or portion thereof is referred to as being “formed”, “disposed” and/or “deposited” on another underlying material, component, layer, region and/or portion, such formation, disposition and/or deposition may be directly and/or indirectly on an exposed layer surface 111 (at the time of such formation, disposition and/or deposition) of such underlying material, component, layer, region and/or portion, with the potential of intervening material(s), component(s), layer(s), region(s) and/or portion(s) therebetween.

In the present disclosure, a directional convention is followed, extending substantially normally relative to the lateral aspect described above, in which the substrate 110 is considered to be the “bottom” of the device 100, and the layers 120, 130, 140 are disposed on “top” of the substrate 110. Following such convention, the second electrode 140 is at the top of the device 100 shown, even if (as may be the case in some examples, including without limitation, during a manufacturing process, in which one or more layers 120, 130, 140 may be introduced by means of a vapor deposition process), the substrate 110 is physically inverted such that the top surface, on which one of the layers 120, 130, 140, such as, without limitation, the first electrode 120, is to be disposed, is physically below the substrate 110, so as to allow the deposition material (not shown) to move upward and be deposited upon the top surface thereof as a thin film.

In some non-limiting examples, the device 100 may be electrically coupled to a power source 15. When so coupled, the device 100 may emit photons as described herein.

In some non-limiting examples, the device 100 may be classified according to a direction of emission of photons generated therefrom. In some non-limiting examples, the device 100 may be considered to be a bottom-emission device if the photons generated are emitted in a direction toward and through the substrate 110 at the bottom of the device 100 and away from the layers 120, 130, 140 disposed on top of the substrate 110. In some non-limiting examples, the device 100 may be considered to be a top-emission device if the photons are emitted in a direction away from the substrate 110 at the bottom of the device 100 and toward and/or through the top layer 140 disposed, with intermediate layers 120, 130, on top of the substrate 110. In some non-limiting examples, the device may be considered to be a double-sided emission device if it is configured to emit photons in both the bottom (toward and through the substrate 110) and top (toward and through the top layer 140).

### Thin Film Formation

The frontplane 10 layers 120, 130, 140 may be disposed in turn on a target exposed layer surface 111 (and/or, in some non-limiting examples, including without limitation, in the case of selective deposition disclosed herein, at least one target region and/or portion of such surface) of an underlying material, which in some non-limiting examples, may be, from time to time, the substrate 110 and intervening lower layers 120, 130, 140, as a thin film. In some non-limiting examples, an electrode 120, 140, may be formed of at least one thin conductive film layer of a conductive coating 830.

The thickness of each layer, including without limitation, layers 120, 130, 140, and of the substrate 110, shown in FIG. 1, and throughout the figures, is illustrative only and not necessarily representative of a thickness relative to another layer 120, 130, 140 (and/or of the substrate 110).

The formation of thin films during vapor deposition on an exposed layer surface 111 of an underlying material involves processes of nucleation and growth. During initial stages of film formation, a sufficient number of vapor monomers (which in some non-limiting examples may be molecules and/or atoms) typically condense from a vapor phase to form initial nuclei on the surface 111 presented, whether of the substrate 110 (or of an intervening lower layer 120, 130, 140). As vapor monomers continue to impinge on such surface, a size and density of these initial nuclei increase to form small clusters or islands. After reaching a saturation island density, adjacent islands typically will start to coalesce, increasing an average island size, while decreasing an island density. Coalescence of adjacent islands may continue until a substantially closed film is formed.

While the present disclosure discusses thin film formation, in reference to at least one layer or coating, in terms of vapor deposition, those having ordinary skill in the relevant art will appreciate that, in some non-limiting examples, various components of the electro-luminescent device 100 may be selectively deposited using a wide variety of techniques, including without limitation, evaporation (including without limitation, thermal evaporation and/or electron beam evaporation), photolithography, printing (including without limitation, ink jet and/or vapor jet printing, reel-to-reel printing and/or micro-contact transfer printing), physical vapor deposition (PVD) (including without limitation, sputtering), chemical vapor deposition (CVD) (including without limitation, plasma-enhanced CVD (PECVD) and/or organic vapor phase deposition (OVPD)), laser annealing, laser-induced thermal imaging (LITI) patterning, atomic-layer deposition (ALD), coating (including without limitation, spin coating, dip coating, line coating and/or spray coating) and/or combinations thereof. Some processes may be used in combination with a shadow mask, which may, in some non-limiting examples, be an open mask and/or fine metal mask (FMM), during deposition of any of various layers and/or coatings to achieve various patterns by masking and/or precluding deposition of a deposited material on certain parts of a surface of an underlying material exposed thereto.

In the present disclosure, the terms “evaporation” and/or “sublimation” may be used interchangeably to refer generally to deposition processes in which a source material is converted into a vapor, including without limitation by heating, to be deposited onto a target surface in, without limitation, a solid state. As will be understood, an evaporation process is a type of PVD process where one or more source materials are evaporated and/or sublimed under a low pressure (including without limitation, a vacuum) environment and deposited on a target surface through de-sublimation of the one or more evaporated source materials. A variety of different evaporation sources may be used for heating a source material, and, as such, it will be appreciated by those having ordinary skill in the relevant art, that the source material may be heated in various ways. By way of non-limiting example, the source material may be heated by an electric filament, electron beam, inductive heating, and/or by resistive heating. In some non-limiting examples, the source material may be loaded into a heated crucible, a heated boat, a Knudsen cell (which may be an effusion evaporator source) and/or any other type of evaporation source.

In some non-limiting examples, a deposition source material may be a mixture. In some non-limiting examples, at least one component of a mixture of a deposition source material may not be deposited during the deposition process (or, in some non-limiting examples, be deposited in a relatively small amount compared to other components of such mixture).

In the present disclosure, a reference to a layer thickness of a material, irrespective of the mechanism of deposition thereof, refers to an amount of the material deposited on a target exposed layer surface 111, which corresponds to an amount of the material to cover the target surface with a uniformly thick layer of the material having the referenced layer thickness. By way of non-limiting example, depositing a layer thickness of 10 nanometers (nm) of material indicates that an amount of the material deposited on the surface corresponds to an amount of the material to form a uniformly thick layer of the material that is 10 nm thick. It will be appreciated that, having regard to the mechanism by which thin films are formed discussed above, by way of non-limiting example, due to possible stacking or clustering of monomers, an actual thickness of the deposited material may be non-uniform. By way of non-limiting example, depositing a layer thickness of 10 nm may yield some parts of the deposited material having an actual thickness greater than 10 nm, or other parts of the deposited material having an actual thickness less than 10 nm. A certain layer thickness of a material deposited on a surface may thus correspond, in some non-limiting examples, to an average thickness of the deposited material across the target surface.

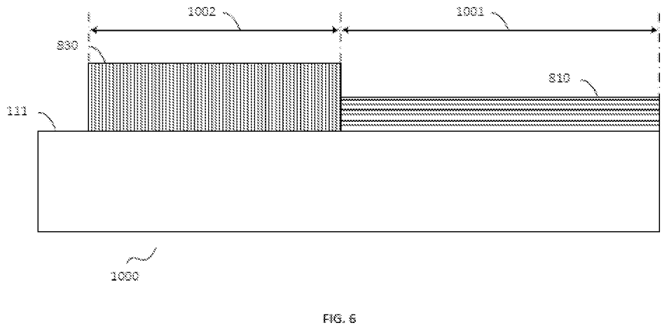

In the present disclosure, a reference to a reference layer thickness refers to a layer thickness of a conductive coating 830 (FIG. 6) that is deposited on a reference surface exhibiting a high initial sticking probability or initial sticking coefficient S₀ (that is, a surface having an initial sticking probability S₀ that is about and/or close to 1). The reference layer thickness does not indicate an actual thickness of the conductive coating 830 deposited on a target surface (such as, without limitation, a surface of a nucleation-inhibiting coating (NIC) 810 (FIG. 6)). Rather, the reference layer thickness refers to a layer thickness of the material for forming the conductive coating 830 that would be deposited on a reference surface, in some non-limiting examples, a surface of a quartz crystal positioned inside a deposition chamber for monitoring a deposition rate and the reference layer thickness, upon subjecting the target surface and the reference surface to identical vapor flux of the material for forming the conductive coating 830 for the same deposition period. Those having ordinary skill in the relevant art will appreciate that in the event that the target surface and the reference surface are not subjected to identical vapor flux simultaneously during deposition, an appropriate tooling factor may be used to determine and/or to monitor the reference layer thickness.

In the present disclosure, a reference to depositing a number X of monolayers of material refers to depositing an amount of the material to cover a desired area of an exposed layer surface 111 with X single layer(s) of constituent monomers of the material.

In the present disclosure, a reference to depositing a fraction 0.X monolayer of a material refers to depositing an amount of the material to cover a fraction 0.X of a desired area of a surface with a single layer of constituent monomers of the material. Those having ordinary skill in the relevant art will appreciate that due to, by way of non-limiting example, possible stacking and/or clustering of monomers, an actual local thickness of a deposited material across a desired area of a surface may be non-uniform. By way of non-limiting example, depositing 1 monolayer of a material may result in some local regions of the desired area of the surface being uncovered by the material, while other local regions of the desired area of the surface may have multiple atomic and/or molecular layers deposited thereon.

In the present disclosure, a target surface (and/or target region(s) thereof) may be considered to be “substantially devoid of”, “substantially free of” and/or “substantially uncovered by” a material if there is a substantial absence of the material on the target surface as determined by any suitable determination mechanism.

In some non-limiting examples, one measure of an amount of a material on a surface is a percentage coverage of the surface by such material. In some non-limiting examples surface coverage may be assessed using a variety of imaging techniques, including without limitation, transmission electron microscopy (TEM), atomic force microscopy (AFM) and/or scanning electron microscopy (SEM).

In some non-limiting examples, one measure of an amount of an electrically conductive material on a surface is a (light) transmittance, since in some non-limiting examples, electrically conductive materials, including without limitation, metals, including without limitation magnesium (Mg), and/or ytterbium (Yb), attenuate and/or absorb photons.

In the present disclosure, for purposes of simplicity of description, the terms “coating film” or “closed film”, as used herein, refer to a thin film structure and/or coating of a material used for a conductive coating 830, in which a relevant portion of a surface is substantially coated thereby, such that such surface is not substantially exposed by or through the coating film deposited thereon. In some non-limiting examples, a coating film of a conductive coating 830 may be disposed to cover a portion of an underlying surface, such that, within such portion, less than about 40%, less than about 30%, less than about 25%, less than about 20%, less than about 15%, less than about 10%, less than about 5%, less than about 3%, or less than about 1% of the underlying surface therewithin is exposed by or through the coating film.

In the present disclosure, for purposes of simplicity of description, the term “discontinuous coating” as used herein, refers to a thin film structure and/or coating of a material used for a conductive coating 830, in which a relevant portion of a surface coated thereby, is neither substantially devoid of such material, or forms a coating film thereof. In some non-limiting examples, a discontinuous coating of a conductive coating 830 may manifest as a plurality of discrete islands and/or discontinuous clusters deposited on such surface.

In the present disclosure, for purposes of simplicity of illustration, details of deposited materials, including without limitation, thickness profiles and/or edge profiles of layer(s) have been omitted.

### Substrate

In some examples, the substrate 110, and in some non-limiting examples, a base substrate 112 thereof, may be formed of material suitable for use therefor, including without limitation, an inorganic material, including without limitation, silicon (Si), glass, metal (including without limitation, a metal foil), sapphire, and/or other suitable inorganic material, and/or an organic material, including without limitation, a polymer, including without limitation, a polyimide and a silicon-based polymer. In some non-limiting examples, the substrate 110 may includes one or more layers of organic and/or inorganic materials formed on a base substrate 112. Non-limiting examples of such materials include, but are not limited to, those used to form electron injection layer(s) (EIL(s)) 139 and/or electron transport layer(s) (ETL(s)) 137.

In some non-limiting examples, additional layers may be provided. Such additional layers may, in some non-limiting examples, comprise and/or be formed of and/or as a backplane layer 20. In some non-limiting examples, the backplane layer 20 contains power circuitry and/or switching elements for driving the device 100, including without limitation, one or more electronic and/or opto-electronic components, including without limitation, thin-film transistor (TFT) transistors, resistors and/or capacitors (collectively TFT structure 200 (FIG. 2)), that, in some non-limiting examples, may be formed by a photolithography process, which uses a photomask to expose selective portions of a photoresist covering an underlying device layer to UV light. Depending on the type of photoresist used, exposed and/or unexposed portions of the photomask may then be washed off to reveal desired portion(s) of the underlying device layer. A patterned surface may then be etched, chemically or physically, to effectively remove an exposed portion of the device layer. In some non-limiting examples, such TFT structures 200 may comprise a semiconductor active area 220 (FIG. 2) formed over a part of buffer layer 210, with a gate insulating layer 230 (FIG. 2) is deposited on substantially cover the semiconductor active area 220. In some non-limiting examples, a gate electrode 240 (FIG. 2) is formed on top of the gate insulating layer 230 and an interlayer insulating layer 250 (FIG. 2) is deposited thereon. In some non-limiting examples, a TFT source electrode 260 (FIG. 2) and a TFT drain electrode 270 (FIG. 2) are formed such that they extend through openings formed through both the interlayer insulating layer 250 and the gate insulating layer 230 such that they are electrically coupled to the semiconductor active area 220. In some non-limiting examples, a TFT insulating layer 280 (FIG. 2) is then formed over the TFT structure 200.

While, in some non-limiting examples, a top-gate TFT structure 200 has been illustrated and described, those having ordinary skill in the relevant art will appreciate that other TFT structures may be used. By way of non-limiting examples, the TFT structure 200 may be a bottom-gate TFT. The TFT structure 200 may be an n-type TFT and/or a p-type TFT. Non-limiting examples of TFT structures include those utilizing amorphous silicon (a-Si), indium gallium zinc oxide (IGZO) and/or low-temperature polycrystalline silicon (LTPS).

Various layers and/or portions of a backplane layer 20, including without limitation, a TFT structure 200, may be fabricated using a variety of suitable materials and/or processes. By way of non-limiting example, the TFT structure 200 may be fabricated using organic and/or inorganic materials, which may be deposited and/or processed by any of the various deposition methodologies described herein, including without limitation, a vapor deposition technique.

### First Electrode

The first electrode 120 is deposited over the substrate 110. In some non-limiting examples, the first electrode 120 is electrically coupled to a terminal of the power source 15 and/or to ground. In some non-limiting examples, the first electrode 120 is so coupled through at least one driving circuit, which in some non-limiting examples, may incorporate at least one TFT structure 200 in the backplane 20 of the substrate 110.

In some non-limiting examples, the first electrode 120 may comprise an anode and/or a cathode. In some non-limiting examples, the first electrode 120 is an anode.

In some non-limiting examples, the first electrode 120 may be formed by depositing at least one thin conductive film, over (a part of) the substrate 110. In some non-limiting examples, there may be a plurality of first electrodes 120, disposed in a spatial arrangement over a lateral aspect of the substrate 110. In some non-limiting examples, one or more of such at least one first electrodes 120 may be electrically coupled to an electrode of the TFT structure 200 in the backplane 20.

In some non-limiting examples, the at least one first electrode 120 and/or at least one thin film thereof, may comprise various materials, including without limitation, one or more metallic materials, including without limitation, Mg, aluminum (Al), calcium (Ca), Zn, Ag, cadmium (Cd), barium (Ba) and/or Yb, and/or combinations thereof, including without limitation, alloys containing any of such materials, one or more metal oxides, including without limitation, a transparent conducting oxide (TCO), including without limitation, ternary compositions such as, without limitation, fluorine tin oxide (FTO), indium zinc oxide (IZO), and/or indium tin oxide (ITO) and/or combinations thereof and/or in varying proportions, and/or combinations thereof in at least one layer, any one or more of which may be, without limitation, a thin film.

### Second Electrode

The second electrode 140 is deposited over the at least one semiconducting layer 130. In some non-limiting examples, the second electrode 140 is electrically coupled to a terminal of the power source 15 and/or to ground. In some non-limiting examples, the second electrode 140 is so coupled through at least one driving circuit 300, which in some non-limiting examples, may incorporate at least one TFT structure 200 in the backplane 20 of the substrate 110.

In some non-limiting examples, the second electrode 140 may comprise an anode and/or a cathode. In some non-limiting examples, the second electrode 130 is a cathode.

In some non-limiting examples, the second electrode 140 may be formed by depositing a conductive coating 830, in some non-limiting examples, as at least one thin film, over (a part of) the at least one semiconducting layer 130. In some non-limiting examples, there may be a plurality of second electrodes 140, disposed in a spatial arrangement over a lateral aspect of the at least one semiconducting layer 130.

In some non-limiting examples, the second electrode 140 includes Yb and Mg. In some other non-limiting examples, the second electrode 140 includes Yb, fullerene, and Mg. For example, the second electrode 140 may include ytterbium fulleride and Mg. Various non-limiting examples of the second electrode 140 are further described elsewhere in the present description.

For purposes of simplicity of description, in the present disclosure, a combination of a plurality of elements in a single layer is denoted by separating two such elements by a colon “:”, while a plurality of (combination(s) of) elements comprising a plurality of layers in a multi-layer coating are denoted by separating two such layers, by a slash “/”. In some non-limiting examples, the layer after the slash may be deposited on the layer preceding the slash.

In some non-limiting examples, for an Mg:Ag alloy, such alloy composition may range from about 1:10 to about 10:1 by volume.

In some non-limiting examples, the second electrode 140 may comprise a plurality of such layers and/or coatings. In some non-limiting examples, such layers and/or coatings may be distinct layers and/or coatings disposed on top of one another.

Semiconducting layer

In some non-limiting examples, the at least one semiconducting layer 130 may comprise a plurality of layers 131, 133, 135, 137, 139, any of which may be disposed, in some non-limiting examples, in a thin film, in a stacked configuration, which may include, without limitation, any one or more of a hole injection layer (HIL) 131, a hole transport layer (HTL) 133, an emissive layer (EML) 135, an ETL 137 and/or an EIL 139. In the present disclosure, the term “semiconducting layer(s)” may be used interchangeably with “organic layer(s)” since the layers 131, 133, 135, 137, 139 in an OLED device 100 may in some non-limiting examples, may comprise organic semiconducting materials.

Those having ordinary skill in the relevant art will readily appreciate that the structure of the device 100 may be varied by omitting and/or combining one or more of the semiconductor layers 131, 133, 135, 137, 139 and/or by introducing one or more additional layers (not shown) at appropriate position(s) within the semiconducting layer 130 stack, including without limitation, a hole blocking layer, an electron blocking layer, a charge generation layer, an efficiency-enhancement layer, and/or additional charge transport and/or injection layers. Each layer may further include any number of sub-layers, and each layer and/or sub-layer may include various mixtures and/or composition gradients. Those having ordinary skill in the relevant art will appreciate that the device 100 may include one or more layers containing inorganic and/or organo-metallic materials and is not limited to devices composed solely of organic materials. By way of non-limiting example, the device 100 may include quantum dots.

In some non-limiting examples, the HIL 131 may be formed using a hole injection material that generally facilitates the injection of holes by the anode, which may, in some non-limiting examples, be the first electrode 120.

In some non-limiting examples, the HTL 133 may be formed using a hole transport material that may be a material exhibiting high hole mobility.

In some non-limiting examples, the EML 135 may be formed, by way of non-limiting example, by doping a host material with at least one emitter material. In some non-limiting examples, the emitter material may be a fluorescent emitter, a phosphorescent emitter, a thermally activated delayed fluorescence (TADF) emitter and/or a plurality of any combination of these.

In some non-limiting examples, the ETL 137 may be formed using an electron transport material that may be a material exhibiting high electron mobility.

In some non-limiting examples, if present, the EIL 139 may be formed using an electron injection material that generally facilitates the injection of electrons by the cathode, which may, in some non-limiting examples, be the second electrode 140.

In some non-limiting examples, the device 100 may be an OLED in which the at least one semiconducting layer 130 comprises at least an EML 135 interposed between conductive thin film electrodes 120, 140, whereby, when a potential difference is applied across them, holes are injected through the anode and electrons are through the cathode into the at least one semiconducting layer 130 until they combine to form a bound state electron-hole pair referred to as an exciton. Especially if the exciton is formed in the EML 135, the exciton may decay through a radiative recombination process, in which a photon is emitted.

In some non-limiting examples, an exciton may decay through a non-radiative process, in which no photon is released, especially if the exciton is not formed in the EML 135.

### Lateral Aspect

In some non-limiting examples, including where the OLED device 100 comprises a lighting panel, an entire lateral aspect of the device 100 may correspond to a single lighting element. As such, the substantially planar cross-sectional profile shown in FIG. 1 may extend substantially along the entire lateral aspect of the device 100, such that photons are emitted from the device 100 substantially along the entirety of the lateral extent thereof. In some non-limiting examples, such single lighting element may be driven by a single driving circuit of the device 100.

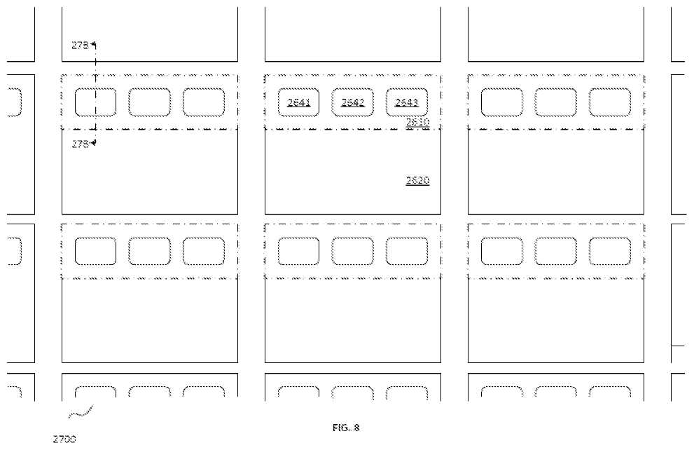

In some non-limiting examples, including where the OLED device 100 comprises a display module, the lateral aspect of the device 100 may be sub-divided into a plurality of emissive regions 2610 (FIG. 8) of the device 100, in which the cross-sectional aspect of the device structure 100, within each of the emissive region(s) 2610 shown, without limitation, in FIG. 1 causes photons to be emitted therefrom when energized.

### Emissive Regions

In some non-limiting examples, individual emissive regions 2610 of the device 100 may be laid out in a lateral pattern. In some non-limiting examples, the pattern may extend along a first lateral direction. In some non-limiting examples, the pattern may also extend along a second lateral direction, which in some non-limiting examples, may be substantially normal to the first lateral direction. In some non-limiting examples, each emissive region 2610 of the device 100 corresponds to a single display pixel. In some non-limiting examples, each pixel emits light at a given wavelength spectrum. In some non-limiting examples, the wavelength spectrum corresponds to a colour in, without limitation, the visible light spectrum.

In some non-limiting examples, each emissive region 2610 of the device 100 corresponds to a sub-pixel 2641-2643 of a display pixel. In some non-limiting examples, a plurality of sub-pixels 2641-2643 may combine to form, or to represent, a single display pixel.

In some non-limiting examples, a single display pixel may be represented by three sub-pixels 2641-2643. In some non-limiting examples, the three sub-pixels 2641-2643 may be denoted as, respectively, R(ed) sub-pixels 2641, G(reen) sub-pixels 2642 and/or B(lue) sub-pixels 2643.

In the present disclosure, the concept of a sub-pixel 2641-2643 may be referenced herein, for simplicity of description only, as a sub-pixel 264x. Likewise, in the present disclosure, the concept of a pixel may be discussed on conjunction with the concept of at least one sub-pixel 264x thereof. For simplicity of description only, such composite concept is referenced herein as a “(sub-) pixel 264x” and such term is understood to suggest either or both of a pixel and/or at least one sub-pixel 64x thereof, unless the context dictates otherwise.

In some non-limiting examples, the emission spectrum of the light emitted by a given sub-pixel 264x corresponds to the colour by which the sub-pixel 264x is denoted. In some non-limiting examples, a sub-pixel 264x is associated with a first set of other sub-pixels 264x to represent a first display pixel and also with a second set of other sub-pixels 264x to represent a second display pixel, so that the first and second display pixels may have associated therewith, the same sub-pixel(s) 264x.

The pattern and/or organization of sub-pixels 264x into display pixels continues to develop. All present and future patterns and/or organizations are considered to fall within the scope of the present disclosure.

### Non-Emissive Regions

In some non-limiting examples, the various emissive regions 2610 of the device 100 are substantially surrounded and separated by, in at least one lateral direction, one or more non-emissive regions , in which the structure and/or configuration along the cross-sectional aspect, of the device structure 100 shown, without limitation, in FIG. 1, is varied, such that no photons are emitted therefrom. In some non-limiting examples, the non-emissive regions comprise those regions in the lateral aspect, that are substantially devoid of an emissive region 2610.

Thus, as shown in the cross-sectional view of FIG. 2, the lateral topology of the various layers of the at least one semiconducting layer 130 may be varied to define at least one emissive region 2610, surrounded (at least in one lateral direction) by at least one non-emissive region.

In some non-limiting examples, the emissive region 2610 corresponding to a single display (sub-) pixel 264x may be understood to have a lateral aspect 410, surrounded in at least one lateral direction by at least one non-emissive region having a lateral aspect 420.

A non-limiting example of an implementation of the cross-sectional aspect of the device 100 as applied to an emissive region 2610 corresponding to a single display (sub-) pixel 264x of an OLED display 100 will now be described. While features of such implementation are shown to be specific to the emissive region 2610, those having ordinary skill in the relevant art will appreciate that in some non-limiting examples, more than one emissive region 2610 may encompass common features.

In some non-limiting examples, the first electrode 120 may be disposed over an exposed layer surface 111 of the device 100, in some non-limiting examples, within at least a part of the lateral aspect 410 of the emissive region 2610. In some non-limiting examples, at least within the lateral aspect 410 of the emissive region 2610 of the (sub-) pixel(s) 264x, the exposed layer surface 111, may, at the time of deposition of the first electrode 120, comprise the TFT insulating layer 280 of the various TFT structures 200 that make up the driving circuit for the emissive region 2610 corresponding to a single display (sub-) pixel 264x.

In some non-limiting examples, the TFT insulating layer 280 may be formed with an opening 430 extending therethrough to permit the first electrode 120 to be electrically coupled to one of the TFT electrodes 240, 260, 270, including, without limitation, by way of the non-limiting example shown in FIG. 2, the TFT drain electrode 270.

In FIG. 2, for purposes of simplicity of illustration, only one TFT structure 200 is shown, but it will be appreciated by those having ordinary skill in the relevant art, that such TFT structure 200 is representative of such plurality thereof that comprise the driving circuit.

In a cross-sectional aspect, the configuration of each emissive region 2610 may, in some non-limiting examples, be defined by the introduction of at least one PDL 440 substantially throughout the lateral aspects 420 of the surrounding non-emissive region(s). In some non-limiting examples, the PDLs 440 may comprise an insulating organic and/or inorganic material.

In some non-limiting examples, the PDLs 440 are deposited substantially over the TFT insulating layer 280, although, as shown, in some non-limiting examples, the PDLs 440 may also extend over at least a part of the deposited first electrode 120 and/or its outer edges.

In some non-limiting examples, as shown in FIG. 2, the cross-sectional thickness and/or profile of the PDLs 440 may impart a substantially valley-shaped configuration to the emissive region 2610 of each (sub-) pixel 264x by a region of increased thickness along a boundary of the lateral aspect 420 of the surrounding non-emissive region with the lateral aspect 410 of the surrounded emissive region 2610, corresponding to a (sub-) pixel 264x.

In some non-limiting examples, the profile of the PDLs 440 may have a reduced thickness beyond such valley-shaped configuration, including without limitation, away from the boundary between the lateral aspect 420 of the surrounding non-emissive region and the lateral aspect 410 of the surrounded emissive region 2610, in some non-limiting examples, substantially well within the lateral aspect 420 of such non-emissive region.

In some non-limiting examples, the at least one semiconducting layer 130 may be deposited over the exposed layer surface 111 of the device 100, including at least a part of the lateral aspects 410 of such emissive region 2610 of the (sub-) pixel(s) 264x. In some non-limiting examples, at least within the lateral aspects 410 of the emissive region 2610 of the (sub-) pixel(s) 264x, such exposed layer surface 111, may, at the time of deposition of the at least one semiconducting layer 130 (and/or layers 131, 133, 135, 137, 139 thereof), comprise the first electrode 120.

In some non-limiting examples, the second electrode 140 may be disposed over an exposed layer surface 111 of the device 100, including at least a part of the lateral aspects 410 of the emissive regions 2610 of the (sub-) pixel(s) 264x. In some non-limiting examples, at least within the lateral aspects 410 of the emissive region 2610 of the (sub-) pixel(s) 264x, such exposed layer surface 111, may, at the time of deposition of the second electrode 130, comprise the at least one semiconducting layer 130.

In some non-limiting examples, the second electrode 140 may also extend beyond the lateral aspects 410 of the emissive regions 2610 of the (sub-) pixel(s) 264x and at least partially within the lateral aspects 420 of the surrounding non-emissive region(s). In some non-limiting examples, such exposed layer surface 111 of such surrounding non-emissive region(s) may, at the time of deposition of the second electrode 140, comprise the PDL(s) 440.

In some non-limiting examples, the second electrode 140 may extend throughout substantially all or a substantial part of the lateral aspects 420 of the surrounding non-emissive region(s).

### Transmissivity

In some non-limiting examples, it may be desirable to make either or both of the first electrode 120 and/or the second electrode 140 substantially photon- (or light)-transmissive (“transmissive”), in some non-limiting examples, at least across a substantial part of the lateral aspect 410 of the emissive region(s) 2610 of the device 100. In the present disclosure, such a transmissive element, including without limitation, an electrode 120, 140, a material from which such element is formed, and/or property of thereof, may comprise an element, material and/or property thereof that is substantially transmissive (“transparent”), and/or, in some non-limiting examples, partially transmissive (“semi-transparent”), in some non-limiting examples, in at least one wavelength range.

In some non-limiting examples, the device 100 is a top-emission device and the second electrode 140 is transmissive and/or transparent or semi-transparent in the visible portion of the electromagnetic spectrum. In some non-limiting examples, the likelihood of the second electrode 140 substantially attenuating an output of light emitted from the device 100 may be reduced by providing a transmissive second electrode 140. In some non-limiting examples, the first electrode 120 is also transmissive.

In some non-limiting examples, a mechanism to make the first electrode 120, and/or the second electrode 140 transmissive is to form such electrode 120, 140 of a transmissive thin film having a relatively small thickness. By way of non-limiting examples, the thickness of the second electrode 140 may be a non-zero value of less than about 100 nm, such as about 60 nm or less, about 50 nm or less, about 40 nm or less, about 35 nm or less, about 30 nm or less, about 25 nm or less, about 20 nm or less, about 15 nm or less, from about 5 nm to about 40 nm, from about 5 nm to about 35 nm, from about 5 nm to about 30 nm. From about 5 nm to about 25 nm, from about 5 nm to about 20 nm, from about 5 nm to about 15 nm, from about 10 nm to about 50 nm, from about 10 nm to about 40 nm, from about 10 nm to about 35 nm, from about 10 nm to about 30 nm, from about 10 nm to about 25 nm, from about 10 nm to about 20 nm, from about 15 nm to about 50 nm, from about 15 nm to about 40 nm, from about 15 nm to about 35 nm, from about 15 nm to about 30 nm, from about 15 nm to about 25 nm, or from about 15 nm to about 20 nm. In some non-limiting examples, an electrically conductive coating 830, in a thin film, including without limitation, those formed by a depositing a thin conductive film layer of a metal, including without limitation, Ag, Mg, Yb, and/or by depositing a thin layer of a metallic alloy, including without limitation, an Mg:Ag alloy and/or a Yb:Ag alloy, may exhibit light-transmissive characteristics. In some non-limiting examples, the alloy may comprise a composition ranging from between about 1:10 to about 10:1 by volume. In some non-limiting examples, the electrode 120, 140 may be formed of a plurality of thin conductive film layers of any combination of conductive coatings 830, any one or more of which may be comprised of TCOs, thin metal films, thin metallic alloy films and/or any combination of any of these.

In some non-limiting examples, especially in the case of such thin conductive films, a relatively thin layer thickness may be up to substantially a few tens of nm so as to contribute to enhanced transmissive qualities but also favorable optical properties (including without limitation, reduced microcavity effects) for use in an OLED device 100.

In some non-limiting examples, a reduction in the thickness of an electrode 120, 140 to promote transmissive qualities may be accompanied by an increase in the sheet resistance of the electrode 120, 140.

In some non-limiting examples, a device 100 having at least one electrode 120, 140 with a high sheet resistance creates a large current-resistance (IR) drop when coupled to the power source 15, in operation. In some non-limiting examples, such an IR drop may be compensated for, to some extent, by increasing a level (VDD) of the power source 15. However, in some non-limiting examples, increasing the level of the power source 15 to compensate for the IR drop due to high sheet resistance, for at least one (sub-) pixel 264x may call for increasing the level of a voltage to be supplied to other components to maintain effective operation of the device 100.

In some non-limiting examples, to reduce power supply demands for a device 100 without significantly impacting an ability to make an electrode 120, 140 substantially transmissive (by employing at least one thin film layer of any combination of TCOs, thin metal films and/or thin metallic alloy films), an auxiliary electrode and/or busbar structure may be formed on the device 100 to allow current to be carried more effectively to various emissive region(s) of the device 100, while at the same time, reducing the sheet resistance and its associated IR drop of the transmissive electrode 120, 140.

By way of non-limiting example, the second electrode 140 may be made transmissive. On the other hand, in some non-limiting examples, such auxiliary electrode and/or busbar 4150 may not be substantially transmissive but may be electrically coupled to the second electrode 140, including without limitation, by deposition of a conductive coating 830 therebetween, to reduce an effective sheet resistance of the second electrode 140.

In some non-limiting examples, such auxiliary electrode may be positioned and/or shaped in either or both of a lateral aspect and/or cross-sectional aspect so as not to interfere with the emission of photons from the lateral aspect 410 of emissive region(s) 2610 of a (sub-) pixel 264x.

In some non-limiting examples, a mechanism to make the first electrode 120, and/or the second electrode 140 is to form such electrode 120, 140 in a pattern across at least a part of the lateral aspect 410 of the emissive region(s) 2610 thereof and/or in some non-limiting examples, across at least a part of the lateral aspect 420 of the non-emissive region(s) surrounding them. In some non-limiting examples, such mechanism may be employed to form the auxiliary electrode and/or busbar in a position and/or shape in either or both of a lateral aspect and/or cross-sectional aspect so as not to interfere with the emission of photons from the lateral aspect 410 of emissive region(s) 2610 of a (sub-) pixel 264x, as discussed above.

In some non-limiting examples, the device 100 may be configured such that it is substantially devoid of a conductive oxide material in an optical path of photons emitted by the device 100. By way of non-limiting example, in the lateral aspect 410 of at least one emissive region 2610 corresponding to a (sub-) pixel 264x, at least one of the layers and/or coatings deposited after the at least one semiconducting layer 130, including without limitation, the second electrode 130, the NIC 810 and/or any other layers and/or coatings deposited thereon, may be substantially devoid of any conductive oxide material. In some non-limiting examples, being substantially devoid of any conductive oxide material may reduce absorption and/or reflection of light emitted by the device 100. By way of non-limiting example, conductive oxide materials, including without limitation, ITO and/or IZO, may absorb light in at least the B(lue) region of the visible spectrum, which may, in generally, reduce efficiency and/or performance of the device 100.

In some non-limiting examples, a combination of these and/or other mechanisms may be employed.

Additionally, in some non-limiting examples, in addition to rendering one or more of the first electrode 120, the second electrode 140, and/or the auxiliary electrode, substantially transmissive across at least across a substantial part of the lateral aspect 410 of the emissive region(s) 2610 corresponding to the (sub-) pixel(s) 264x of the device 100, in order to allow photons to be emitted substantially across the lateral aspect(s) 410 thereof, it may be desired to make at least one of the lateral aspect(s) 420 of the non-emissive region(s) of the device 100 substantially transmissive in both the bottom and top directions, so as to render the device 100 substantially transmissive relative to light incident on an external surface thereof, such that a substantial part such externally-incident light may be transmitted through the device 100, in addition to the emission (in a top-emission, bottom-emission and/or double-sided emission) of photons generated internally within the device 100 as disclosed herein.

Conductive coating

In the present disclosure, the terms “conductive coating” and “electrode coating” may be used interchangeably to refer to similar concepts and references to a conductive coating 830 herein, in the context of being patterned by selective deposition of an NIC 810 may, in some non-limiting examples, be applicable to an electrode coating in the context of being patterned by selective deposition of a patterning coating. In some non-limiting examples, reference to an electrode coating may signify a coating having a specific composition as described herein.

In some non-limiting examples, the conductive coating 830 includes Zn, Mg, Yb, lithium (Li), calcium (Ca), indium (In), Ba, manganese (Mn), Ag, Al, copper (Cu), gold (Au), iron (Fe), cobalt (Co), nickel (Ni), palladium (Pd), platinum (Pt), yttrium (Y), and/or lanthanum (La).

In some non-limiting examples, the conductive coating 830 includes at least one of: Ag, Mg, Yb, and Zn. In some non-limiting examples, the conductive coating 830 includes Mg, and/or Yb.

In some non-limiting examples, the conductive coating material 831 used to deposit a conductive coating 830 onto an exposed layer surface 111, may be a substantially pure element. In some further non-limiting examples, the conductive coating 830 includes a substantially pure element. In some other non-limiting examples, the conductive coating 830 includes two or more elements, which may for example be presented as an alloy or a mixture.

In some non-limiting examples, the conductive coating 830 includes one or more additional elements to the element(s) described above. Non-limiting examples of such additional elements include oxygen (O), sulfur (S), nitrogen (N), and carbon (C). It will be appreciated by those having ordinary skill in the relevant art that such one or more additional elements may be incorporated into the conductive coating 830 intentionally, or as a contaminant due to the presence of such additional element(s) in the source material, equipment used for deposition, and/or the vacuum chamber environment. In some non-limiting examples, such additional elements may form a compound together with the element(s) of the conductive coating 830.

In some non-limiting examples, the conductive coating material 831 used to deposit a conductive coating 830 onto an exposed layer surface 111, including without limitation, Mg, may be substantially pure.

### Patterning

As a result of the foregoing, it may be desirable to selectively deposit, across the lateral aspect 410 of the emissive region 2610 of a (sub-) pixel 264x and/or the lateral aspect 420 of the non-emissive region(s) surrounding the emissive region 2610, a device feature, including without limitation, at least one of the first electrode 120, the second electrode 140, the auxiliary electrode and/or busbar and/or a conductive element electrically coupled thereto, in a pattern, on an exposed layer surface 111 of a frontplane 10 layer of the device 100. In some non-limiting examples, the first electrode 120, the second electrode 140, the auxiliary electrode and/or the busbar may be deposited in at least one of a plurality of conductive coatings 830.

However, it may not be feasible to employ a shadow mask such as an FMM that may, in some non-limiting examples, be used to form relatively small features, with a feature size on the order of tens of microns or smaller to achieve such patterning of a conductive coating 830, since, in some non-limiting examples:
an FMM may be deformed during a deposition process, especially at high temperatures, such as may be employed for deposition of a thin conductive film;
limitations on the mechanical (including, without limitation, tensile) strength of the FMM and/or shadowing effects, especially in a high-temperature deposition process, may impart a constraint on an aspect ratio of features that may be achievable using such FMMs;
the type and number of patterns that may be achievable using such FMMs may be constrained since, by way of non-limiting example, each part of the FMM will be physically supported so that, in some non-limiting examples, some patterns may not be achievable in a single processing stage, including by way of non-limiting example, where a pattern specifies an isolated feature;
FMMs may exhibit a tendency to warp during a high-temperature deposition process, which may, in some non-limiting examples, distort the shape and position of apertures therein, which may cause the selective deposition pattern to be varied, with a degradation in performance and/or yield;
FMMs that may be used to produce repeating structures spread across the entire surface of a device 100, may call for a large number of apertures to be formed in the FMM, which may compromise the structural integrity of the FMM;
repeated use of FMMs in successive depositions, especially in a metal deposition process, may cause the deposited material to adhere thereto, which may obfuscate features of the FMM and which may cause the selective deposition pattern to be varied, with a degradation in performance and/or yield;
while FMMs may be periodically cleaned to remove adhered non-metallic material, such cleaning procedures may not be suitable for use with adhered metal, and even so, in some non-limiting examples, may be time-consuming and/or expensive; and
irrespective of any such cleaning processes, continued use of such FMMs, especially in a high-temperature deposition process, may render them ineffective at producing a desired patterning, at which point they may be discarded and/or replaced, in a complex and expensive process.
   Nucleation-Inhibiting and/or Promoting Material Properties

In some non-limiting examples, a conductive coating 830, that may be employed as, or as at least one of a plurality of layers of thin conductive films to form a device feature, including without limitation, at least one of the first electrode 120, the second electrode 140, an auxiliary electrode and/or a busbar and/or a conductive element electrically coupled thereto, may exhibit a relatively low affinity towards being deposited on an exposed layer surface 111 of an underlying material, so that the deposition of the conductive coating 830 is inhibited.

The relative affinity or lack thereof of a material and/or a property thereof to having a conductive coating 830 deposited thereon may be referred to as being “nucleation-promoting” or “nucleation-inhibiting” respectively.

In the present disclosure, “nucleation-inhibiting” refers to a coating, material and/or a layer thereof that has a surface that exhibits a relatively low affinity for (deposition of) a conductive coating 830 thereon, such that the deposition of the conductive coating 830 on such surface is inhibited.

In the present disclosure, “nucleation-promoting” refers to a coating, material and/or a layer thereof that has a surface that exhibits a relatively high affinity for (deposition of) a conductive coating 830 thereon, such that the deposition of the conductive coating 830 on such surface is facilitated.

The term “nucleation” in these terms references the nucleation stage of a thin film formation process, in which monomers in a vapor phase condense onto the surface to form nuclei.

Without wishing to be bound by a particular theory, it is postulated that the shapes and sizes of such nuclei and the subsequent growth of such nuclei into islands and thereafter into a thin film may depend upon a number of factors, including without limitation, interfacial tensions between the vapor, the surface and/or the condensed film nuclei.

In the present disclosure, such affinity may be measured in a number of fashions.

One measure of a nucleation-inhibiting and/or nucleation-promoting property of a surface is the initial sticking probability S₀ of the surface for a given electrically conductive material, including without limitation, Mg. In the present disclosure, the terms “sticking probability” and “sticking coefficient” may be used interchangeably.

In some non-limiting examples, the sticking probability S may be given by:

$$S = \frac{{N}_{ads}}{{N}_{total}}$$

where N_{ads} is a number of adsorbed monomers (“adatoms”) that remain on an exposed layer surface 111 (that is, are incorporated into a film) and Nₜₒₜₐₗ is a total number of impinging monomers on the surface. A sticking probability S equal to 1 indicates that all monomers that impinge on the surface are adsorbed and subsequently incorporated into a growing film. A sticking probability S equal to 0 indicates that all monomers that impinge on the surface are desorbed and subsequently no film is formed on the surface. A sticking probability S of metals on various surface can be evaluated using various techniques of measuring the sticking probability S, including without limitation, a dual quartz crystal microbalance (QCM) technique as described by Walker et al., J. Phys. Chem. C 2007, 111, 765 (2006).

As the density of islands increases (e.g., increasing average film thickness), a sticking probability S may change. By way of non-limiting example, a low initial sticking probability S₀ may increase with increasing average film thickness. This can be understood based on a difference in sticking probability S between an area of a surface with no islands, by way of non-limiting example, a bare substrate 110, and an area with a high density of islands. By way of non-limiting example, a monomer that impinges on a surface of an island may have a sticking probability S that approaches 1.

An initial sticking probability S₀ may therefore be specified as a sticking probability S of a surface prior to the formation of any significant number of critical nuclei. One measure of an initial sticking probability S₀ can involve a sticking probability S of a surface for a material during an initial stage of deposition of the material, where an average thickness of the deposited material across the surface is at or below a threshold value. In the description of some non-limiting examples a threshold value for an initial sticking probability S₀ can be specified as, by way of non-limiting example, 1 nm. An average sticking probability S̅ may then be given by:

S̅=S₀(1−A_{nuc})+S_{nuc}(A_{nuc})

where S_{nuc} is a sticking probability S of an area covered by islands, and A_{nuc} is a percentage of an area of a substrate surface covered by islands.

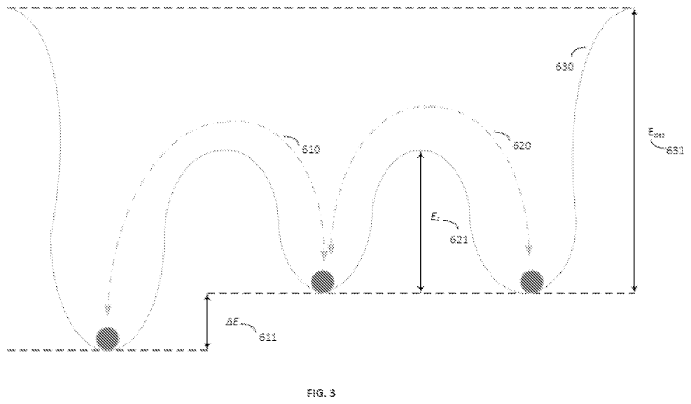

An example of an energy profile of an adatom adsorbed onto an exposed layer surface 111 of an underlying material (in the figure, the substrate 110) is illustrated in FIG. 3. Specifically, FIG. 3 illustrates example qualitative energy profiles corresponding to:

an adatom escaping from a local low energy site (610); diffusion of the adatom on the exposed layer surface 111 (620); and desorption of the adatom (630).

In 610, the local low energy site may be any site on the exposed layer surface 111 of an underlying material, onto which an adatom will be at a lower energy. Typically, the nucleation site may comprise a defect and/or an anomaly on the exposed layer surface 111, including without limitation, a step edge, a chemical impurity, a bonding site and/or a kink. Once the adatom is trapped at the local low energy site, there may in some non-limiting examples, typically be an energy barrier before surface diffusion takes place. Such energy barrier is represented as ΔE 611 in FIG. 3. In some non-limiting examples, if the energy barrier ΔE 611 to escape the local low energy site is sufficiently large the site may act as a nucleation site.

In 620, the adatom may diffuse on the exposed layer surface 111. By way of non-limiting example, in the case of localized absorbates, adatoms tend to oscillate near a minimum of the surface potential and migrate to various neighboring sites until the adatom is either desorbed, and/or is incorporated into a growing film and/or growing islands formed by a cluster of adatoms. In FIG. 3, the activation energy associated with surface diffusion of adatoms is represented as Eₛ 621.

In 630, the activation energy associated with desorption of the adatom from the surface is represented as E_{des} 631. Those having ordinary skill in the relevant art will appreciate that any adatoms that are not desorbed may remain on the exposed layer surface 111. By way of non-limiting example, such adatoms may diffuse on the exposed layer surface 111, be incorporated as part of a growing film and/or coating, and/or become part of a cluster of adatoms that form islands on the exposed layer surface 111.

Based on the energy profiles 610, 620, 630 shown in FIG. 3, it may be postulated that NIC 810 materials exhibiting relatively low activation energy for desorption (E_{des} 631) and/or relatively high activation energy for surface diffusion (Eₛ 631) may be particularly advantageous for use in various applications.

One measure of a nucleation-inhibiting and/or nucleation-promoting property of a surface is an initial deposition rate of a given electrically conductive material, on the surface, relative to an initial deposition rate of the same conductive material on a reference surface, where both surfaces are subjected to and/or exposed to an evaporation flux of the conductive material.

In some non-limiting examples, suitable materials for use to form an NIC 810, may include those exhibiting and/or characterized as having an initial sticking probability S₀ for a material of a conductive coating 830 of no greater than and/or less than about 0.3 (or 30%), no greater than and/or less than about 0.2, no greater than and/or less than about 0.15, no greater than and/or less than about 0.1, no greater than and/or less than about 0.08, no greater than and/or less than about 0.05, no greater than and/or less than 0.03, no greater than and/or less than about 0.02, no greater than and/or less than 0.01, no greater than and/or less than 0.008, no greater than and/or less than about 0.005, no greater than and/or less than about 0.003, no greater than and/or less than 0.001, no greater than and/or less than about 0.0008, no greater than and/or less than about 0.0005, and/or no greater than and/or less than about 0.0001.

In some non-limiting examples, suitable materials for use to form an NIC 810 include those exhibiting and/or characterized has having initial sticking probability S₀ for a material of a conductive coating 830 of between about 0.15 and about 0.0001, between about 0.1 and about 0.0003, between about 0.08 and about 0.0005, between about 0.08 and about 0.0008, between about 0.05 and about 0.001, between about 0.03 and about 0.005, between about 0.03 and about 0.008, between about 0.03 and about 0.01, between about 0.02 and about 0.0001, between about 0.02 and about 0.0003, between about 0.02 and about 0.0005, between about 0.02 and about 0.0008, between about 0.02 and about 0.0005, between about 0.02 and about 0.0008, between about 0.02 and about 0.001, between about 0.02 and about 0.005, between about 0.02 and about 0.008, between about 0.02 and about 0.01, between about 0.01 and about 0.0001, between about 0.01 and about 0.0003, between about 0.01 and about 0.0005, between about 0.01 and about 0.0008, between about 0.01 and about 0.001, between about 0.01 and about 0.005, between about 0.01 and about 0.008, between about 0.008 and about 0.0001, between about 0.008 and about 0.0003, between about 0.008 and about 0.0005, between about 0.008 and about 0.0008, between about 0.008 and about 0.001, between about 0.008 and about 0.005, between about 0.005 and about 0.0001, between about 0.005 and about 0.0003, between about 0.005 and about 0.0005, between about 0.005 and about 0.0008, and/or between about 0.005 and about 0.001.

In some non-limiting examples, suitable materials for use to form an NIC 810 include those exhibiting and/or characterized has having initial sticking probability S₀ of or below a threshold value for two or more different elements. In some non-limiting examples, the NIC 810 exhibits S₀ of or below a threshold value for two or more elements selected from: Mg, Yb, Cd, and Zn. In some further non-limiting examples, the NIC 810 exhibits S₀ of or below a threshold value for Mg, and Yb. In some non-limiting examples, the threshold value may be about 0.3, about 0.2, about 0.18, about 0.15, about 0.13, about 0.1, about 0.08, about 0.05, about 0.03, about 0.02, about 0.01, about 0.08, about 0.005, about 0.003, or about 0.001.

Selective Coatings for Impacting Nucleation-Inhibiting and/or Promoting Material Properties

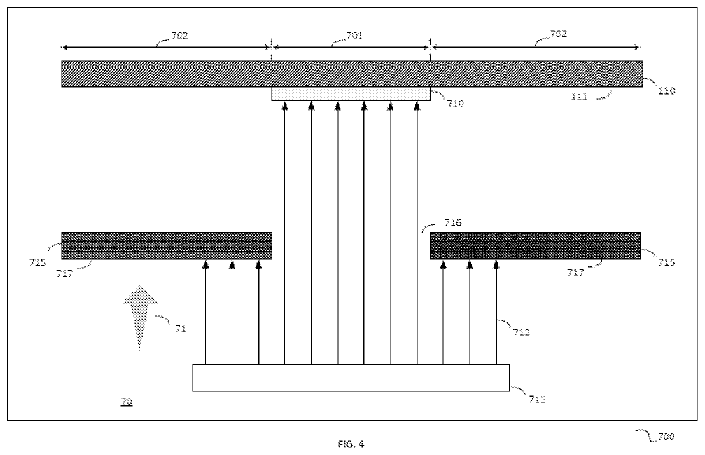

In some non-limiting examples, one or more selective coatings 710 may be selectively deposited on at least a first portion 701 (FIG. 4) of an exposed layer surface 111 of an underlying material to be presented for deposition of a thin film conductive coating 830 thereon. Such selective coating(s) 710 have a nucleation-inhibiting property (and/or conversely a nucleation-promoting property) with respect to the conductive coating 830 that differs from that of the exposed layer surface 111 of the underlying material. In some non-limiting examples, there may be a second portion 702 (FIG. 4) of the exposed layer surface 111 of an underlying material to which no such selective coating(s) 710, has been deposited.

Such a selective coating 710 may be an NIC 810 and/or a nucleation-promoting coating (NPC).

In the present disclosure, the terms “NIC” and “patterning coating” may be used interchangeably to refer to similar concepts, and references to an NIC 810 herein, in the context of being selectively deposited to pattern a conductive coating 830 may, in some non-limiting examples, be applicable to a patterning coating in the context of selective deposition thereof to pattern an electrode coating. In some non-limiting examples, reference to a patterning coating may signify a coating having a specific composition as described herein.

It will be appreciated by those having ordinary skill in the relevant art that the use of such a selective coating 710 may, in some non-limiting examples, facilitate and/or permit the selective deposition of the conductive coating 830 without employing an FMM during the stage of depositing the conductive coating 830.

In some non-limiting examples, such selective deposition of the conductive coating 830 may be in a pattern. In some non-limiting examples, such pattern may facilitate providing and/or increasing transmissivity of at least one of the top and/or bottom of the device 100, within the lateral aspect 410 of one or more emissive region(s) 2610 of a (sub-) pixel 264x and/or within the lateral aspect 420 of one or more non-emissive region(s) that may, in some non-limiting examples, surround such emissive region(s) 2610.

In some non-limiting examples, the conductive coating 830 may be deposited on a conductive structure and/or in some non-limiting examples, form a layer thereof, for the device 100, which in some non-limiting examples may be the first electrode 120 and/or the second electrode 140 to act as one of an anode 341 and/or a cathode 342, and/or an auxiliary electrode and/or busbar to support conductivity thereof and/or in some non-limiting examples, be electrically coupled thereto.

In some non-limiting examples, an NIC 810 for a given conductive coating 830, may refer to a coating having a surface that exhibits a relatively low initial sticking probability S₀ for the conductive coating 830 in vapor form, such that deposition of the conductive coating 830 onto the exposed layer surface 111 is inhibited. Thus, in some non-limiting examples, selective deposition of an NIC 810 may reduce an initial sticking probability S₀ of an exposed layer surface 111 (of the NIC 810) presented for deposition of the conductive coating 830 thereon.

In some non-limiting examples, an NPC, for a given conductive coating 830, may refer to a coating having an exposed layer surface 111 that exhibits a relatively high initial sticking probability S₀ for the conductive coating 830 in vapor form, such that deposition of the conductive coating 830 onto the exposed layer surface 111 is facilitated. Thus, in some non-limiting examples, selective deposition of an NPC may increase an initial sticking probability S₀ of an exposed layer surface 111 (of the NPC) presented for deposition of the conductive coating 830 thereon.

When the selective coating 710 is an NIC 810, the first portion 701 of the exposed layer surface 111 of the underlying material, upon which the NIC 810 is deposited, will thereafter present a treated surface (of the NIC 810) whose nucleation-inhibiting property has been increased or alternatively, whose nucleation-promoting property has been reduced (in either case, the surface of the NIC 810 deposited on the first portion 701), such that it has a reduced affinity for deposition of the conductive coating 830 thereon relative to that of the exposed layer surface 111 of the underlying material upon which the NIC 810 has been deposited. By contrast the second portion 702, upon which no such NIC 810 has been deposited, will continue to present an exposed layer surface 111 (of the underlying substrate 110) whose nucleation-inhibiting property or alternatively, whose nucleation-promoting property (in either case, the exposed layer surface 111 of the underlying substrate 110 that is substantially devoid of the selective coating 710), has an affinity for deposition of the conductive coating 830 thereon that has not been substantially altered.

When the selective coating 710 is an NPC, the first portion 701 of the exposed layer surface 111 of the underlying material, upon which the NPC is deposited, will thereafter present a treated surface (of the NPC) whose nucleation-inhibiting property has been reduced or alternatively, whose nucleation-promoting property has been increased (in either case, the surface of the NPC deposited on the first portion 701), such that it has an increased affinity for deposition of the conductive coating 830 thereon relative to that of the exposed layer surface 111 of the underlying material upon which the NPC has been deposited. By contrast, the second portion 702, upon which no such NPC has been deposited, will continue to present an exposed layer surface 111 (of the underlying substrate 110) whose nucleation-inhibiting property or alternatively, whose nucleation-promoting property (in either case, the exposed layer surface 111 of the underlying substrate 110 that is substantially devoid of the NPC), has an affinity for deposition of the conductive coating 830 thereon that has not been substantially altered.

In some non-limiting examples, both an NIC 810 and an NPC may be selectively deposited on respective first portions 701 and NPC portions of an exposed layer surface 111 of an underlying material to respectively alter a nucleation-inhibiting property (and/or conversely a nucleation-promoting property) of the exposed layer surface 111 to be presented for deposition of a conductive coating 830 thereon. In some non-limiting examples, there may be a second portion 702 of the exposed layer surface 111 of an underlying material to which no selective coating 710 has been deposited, such that the nucleation-inhibiting property (and/or conversely its nucleation-promoting property) to be presented for deposition of the conductive coating 830 thereon is not substantially altered.

In some non-limiting examples, the first portion 701 and NPC portion may overlap, such that a first coating of an NIC 810 and/or an NPC may be selectively deposited on the exposed layer surface 111 of the underlying material in such overlapping region and the second coating of the NIC 810 and/or the NPC may be selectively deposited on the treated exposed layer surface 111 of the first coating. In some non-limiting examples, the first coating is an NIC 810. In some non-limiting examples, the first coating is an NPC.

In some non-limiting examples, the first portion 701 (and/or NPC portion) to which the selective coating 710 has been deposited, may comprise a removal region, in which the deposited selective coating 710 has been removed, to present the uncovered surface of the underlying material for deposition of the conductive coating 830 thereon, such that the nucleation-inhibiting property (and/or conversely its nucleation-promoting property) to be presented for deposition of the conductive coating 830 thereon is not substantially altered.

In some non-limiting examples, the underlying material may be at least one layer selected from the substrate 110 and/or at least one of the frontplane 10 layers, including without limitation, the first electrode 120, the second electrode 140, the at least one semiconducting layer 130 (and/or at least one of the layers thereof) and/or any combination of any of these.

In some non-limiting examples, the conductive coating 830 may have specific material properties. In some non-limiting examples, the conductive coating 830 may comprise Mg, whether alone or in a compound and/or alloy.

By way of non-limiting example, pure and/or substantially pure Mg may not be readily deposited onto some organic surfaces due to a low sticking probability S of Mg on some organic surfaces.

### Deposition of Selective Coatings

In some non-limiting examples, a thin film comprising the selective coating 710, may be selectively deposited and/or processed using a variety of techniques, including without limitation, evaporation (including without limitation), thermal evaporation and/or electron beam evaporation), photolithography, printing (including without limitation, ink jet and/or vapor jet printing, reel-to-reel printing and/or micro-contact transfer printing), PVD (including without limitation, sputtering), CVD (including without limitation, PECVD and/or OVPD), laser annealing, LITI patterning, ALD, coating (including without limitation, spin coating, dip coating, line coating and/or spray coating) and/or combinations thereof.

FIG. 4 is an example schematic diagram illustrating a non-limiting example of an evaporative process, shown generally at 700, in a chamber 70, for selectively depositing a selective coating 710 onto a first portion 701 of an exposed layer surface 111 of an underlying material (in the figure, for purposes of simplicity of illustration only, the substrate 110).

In the process 700, a quantity of a selective coating material 711, is heated under vacuum, to evaporate and/or sublime 712 the selective coating material 711. In some non-limiting examples, the selective coating material 711 comprises entirely, and/or substantially, a material used to form the selective coating 710. Evaporated selective coating material 712 is directed through the chamber 70, including in a direction indicated by arrow 71, toward the exposed layer surface 111. When the evaporated selective coating material 712 is incident on the exposed layer surface 111, that is, in the first portion 701, the selective coating 710 is formed thereon.

In some non-limiting examples, as shown in the figure for the process 700, the selective coating 710 may be selectively deposited only onto a portion, in the example illustrated, the first portion 701, of the exposed layer surface 111, by the interposition, between the selective coating material 711 and the exposed layer surface 111, of a shadow mask 715, which in some non-limiting examples, may be an FMM. The shadow mask 715 has at least one aperture 716 extending therethrough such that a part of the evaporated selective coating material 712 passes through the aperture 716 and is incident on the exposed layer surface 111 to form the selective coating 710. Where the evaporated selective coating material 712 does not pass through the aperture 716 but is incident on the surface 717 of the shadow mask 715, it is precluded from being disposed on the exposed layer surface 111 to form the selective coating 710 within the second portion 702. The second portion 702 of the exposed layer surface 111 is thus substantially devoid of the selective coating 710. In some non-limiting examples (not shown), the selective coating material 711 that is incident on the shadow mask 715 may be deposited on the surface 717 thereof.

Accordingly, a patterned surface is produced upon completion of the deposition of the selective coating 710.

In some non-limiting examples, for purposes of simplicity of illustration, the selective coating 710 employed in FIG. 4 may be an NIC 810. In some non-limiting examples, for purposes of simplicity of illustration, the selective coating 710 employed in FIG. 4 may be an NPC.

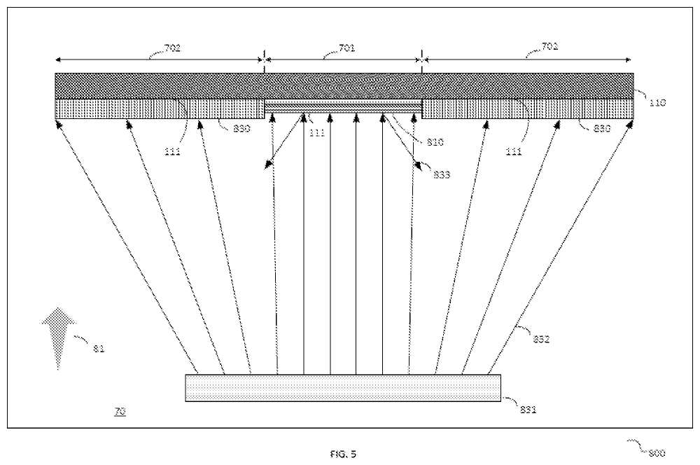

FIG. 5 is an example schematic diagram illustrating a non-limiting example of a result of an evaporative process, shown generally at 800, in a chamber 70, for selectively depositing a conductive coating 830 onto a second portion 702 of an exposed layer surface 111 of an underlying material (in the figure, for purposes of simplicity of illustration only, the substrate 110) that is substantially devoid of the NIC 810 that was selectively deposited onto a first portion 701, including without limitation, by the evaporative process 700 of FIG. 4. In some non-limiting examples, the second portion 702 comprises that portion of the exposed layer surface 111 that lies beyond the first portion 701.

Once the NIC 810 has been deposited on a first portion 701 of an exposed layer surface 111 of an underlying material (in the figure, the substrate 110), the conductive coating 830 may be deposited on the second portion 702 of the exposed layer surface 111 that is substantially devoid of the NIC 810.

In the process 800, a quantity of a conductive coating material 831, is heated under vacuum, to evaporate and/or sublime 832 the conductive coating material 831. In some non-limiting examples, the conductive coating material 831 comprises entirely, and/or substantially, a material used to form the conductive coating 830. Evaporated conductive coating material 832 is directed inside the chamber 70, including in a direction indicated by arrow 81, toward the exposed layer surface 111 of the first portion 701 and of the second portion 702. When the evaporated conductive coating material 832 is incident on the second portion 702 of the exposed layer surface 111, the conductive coating 830 is formed thereon.

In some non-limiting examples, deposition of the conductive coating material 831 may be performed using an open mask and/or mask-free deposition process, such that the conductive coating 830 is formed substantially across the entire exposed layer surface 111 of the underlying material (in the figure, the substrate 110) to produce a treated surface (of the conductive coating 830).

It will be appreciated by those having ordinary skill in the relevant art that, contrary to that of an FMM, the feature size of an open mask is generally comparable to the size of a device 100 being manufactured. In some non-limiting examples, such an open mask may have an aperture that may generally correspond to a size of the device 100, which in some non-limiting examples, may correspond, without limitation, to about 1 inch for micro-displays, about 4-6 inches for mobile displays, and/or about 8-17 inches for laptop and/or tablet displays, so as to mask edges of such device 100 during manufacturing. In some non-limiting examples, the feature size of an open mask may be on the order of about 1 cm and/or greater. In some non-limiting examples, an aperture formed in an open mask may in some non-limiting examples be sized to encompass the lateral aspect(s) 410 of a plurality of emissive regions 2610 each corresponding to a (sub-) pixel 264x and/or surrounding and/or the lateral aspect(s) 420 of surrounding and/or intervening non-emissive region(s).

It will be appreciated by those having ordinary skill in the relevant art that, in some non-limiting examples, the use of an open mask may be omitted, if desired. In some non-limiting examples, an open mask deposition process described herein may alternatively be conducted without the use of an open mask, such that an entire target exposed layer surface 111 may be exposed.

In some non-limiting examples, as shown in the figure for the process 800, deposition of the conductive coating 830 may be performed using an open mask and/or mask-free deposition process, such that the conductive coating 830 is formed substantially across the entire exposed layer surface 111 of the underlying material (in the figure, of the substrate 110) to produce a treated surface (of the conductive coating 830).

Indeed, as shown in FIG. 5, the evaporated conductive coating material 832 is incident both on an exposed layer surface 111 of NIC 810 across the first portion 701 as well as the exposed layer surface 111 of the substrate 110 across the second portion 702 that is substantially devoid of NIC 810.

Since the exposed layer surface 111 of the NIC 810 in the first portion 701 exhibits a relatively low initial sticking probability S₀ for the conductive coating 830 compared to the exposed layer surface 111 of the substrate 110 in the second portion 702, the conductive coating 830 is selectively deposited substantially only on the exposed layer surface 111 of the substrate 110 in the second portion 702 that is substantially devoid of the NIC 810. By contrast, the evaporated conductive coating material 832 incident on the exposed layer surface 111 of NIC 810 across the first portion 701 tends not to be deposited, as shown (833) and the exposed layer surface 111 of NIC 810 across the first portion 701 is substantially devoid of the conductive coating 830.

The foregoing may be combined in order to effect the selective deposition of at least one conductive coating 830 to form a device feature, including without limitation, a patterned electrode 120, 140, and/or a conductive element electrically coupled thereto, without employing an FMM within the conductive coating 830 deposition process. In some non-limiting examples, such patterning may permit and/or enhance the transmissivity of the device 100.

In some non-limiting examples, the selective coating 710, which may be an NIC 810 and/or an NPC may be applied a plurality of times during the manufacturing process of the device 100, in order to pattern a device feature comprising a plurality of electrodes 120, 140, and/or various layers thereof and/or a conductive coating 830 electrically coupled thereto.

In some non-limiting examples, a thickness of the selective coating 710, such as an NIC 810, and of the conductive coating 830 deposited thereafter may be varied according to a variety of parameters, including without limitation, a desired application and desired performance characteristics. In some non-limiting examples, the thickness of the NIC 810 may be comparable to and/or substantially less than a thickness of conductive coating 830 deposited thereafter. Use of a relatively thin NIC 810 to achieve selective patterning of a conductive coating deposited thereafter may be suitable to provide flexible devices 100. In some non-limiting examples, a relatively thin NIC 810 may provide a relatively planar surface on which a barrier coating or other thin film encapsulation (TFE) layer, may be deposited. In some non-limiting examples, providing such a relatively planar surface for application of the barrier coating may increase adhesion of the barrier coating 1650 to the device.

Turning now to FIG. 6, there is shown an example version 1000 of a simplified version of the device 100 shown in FIG. 1, but with a number of additional deposition steps that are described herein.

The device 1000 shows a lateral aspect of the exposed layer surface 111 of the underlying material. The lateral aspect comprises a first portion 1001 and a second portion 1002. In the first portion 1001, an NIC 810 is disposed on the exposed layer surface 111. However, in the second portion 1002, the exposed layer surface 111 is substantially devoid of the NIC 810.

After selective deposition of the NIC 810 across the first portion 1001, the conductive coating 830 is deposited over the device 1000, in some non-limiting examples, using an open mask and/or a mask-free deposition process, but remains substantially only within the second portion 1002, which is substantially devoid of NIC 810.

While the surface of the NIC 810 is described in some non-limiting examples as being substantially devoid of the material for forming the conductive coating 830, in some non-limiting examples, the surface of the NIC 810 is not substantially devoid of the material for forming the conductive coating 830, but nevertheless does not amount to a closed or coating film of the conductive coating 830.

Rather, in some non-limiting examples, some vapor monomers of the material(s) for forming the conductive coating 830 impinging on the surface of the NIC 810, may condense to form small clusters or islands thereon. However, substantial growth of such clusters or islands which, if left unimpeded, may lead to possible formation of a substantially closed coating film of the material(s) for forming the conductive coating on the surface of the NIC 810, is inhibited due to one or more properties and/or features of the NIC 810.

Thus, in some non-limiting examples, the surface of the NIC 810 may have a discontinuous coating (not shown) of the material of the conductive coating 830 deposited thereon.

In some non-limiting examples, such a discontinuous coating is a thin film coating comprising a plurality of discrete islands. In some non-limiting examples, at least some of the islands are disconnected from one another. In other words, the discontinuous coating may, in some non-limiting examples, comprise features that are physically separated from one another such that the discontinuous coating does not form a continuous layer that comprises a closed or coating film.

Accordingly, in some non-limiting examples, the surface of the NIC 810 is substantially devoid of a closed film of the conductive coating.

The NIC 810 provides, within the first portion 1001, a surface with a relatively low initial sticking probability S₀, for the conductive coating 830, and that is substantially less than the initial sticking probability S₀, for the conductive coating 830, of the exposed layer surface 111 of the underlying material of the device 1000 within the second portion 1002.

Thus, the first portion 1001 is substantially devoid of the conductive coating 830.

In this fashion, the NIC 810 may be selectively deposited, including using a shadow mask, to allow the conductive coating 830 to be deposited, including without limitation, using an open mask and/or a mask-free deposition process, so as to form a device feature, including without limitation, at least one of the first electrode 120, the second electrode 140, the auxiliary electrode, a busbar and/or at least one layer thereof, and/or a conductive element electrically coupled thereto.

### Auxiliary Electrode

In some non-limiting examples, the second electrode 140 may comprise an electrode that is common to all (sub-) pixels of the device (common electrode) and an auxiliary electrode may be deposited in a pattern, in some non-limiting examples, above or in some non-limiting examples below the second electrode 140 and electrically coupled thereto. In some non-limiting examples, the pattern for such auxiliary electrode may be such that spaced-apart regions lie substantially within the lateral aspect(s) 420 of non-emissive region(s) surrounding the lateral aspect(s) 410 of emissive region(s) 2610 corresponding to (sub-) pixel(s) 264x. In some non-limiting examples, the pattern for such auxiliary electrodes may be such that the elongated spaced-apart regions thereof lie substantially within the lateral aspect(s) 410 of emissive region(s) 2610 corresponding to (sub-) pixel(s) 264x and/or the lateral aspect(s) 420 of non-emissive region(s) surrounding them.

The auxiliary electrode is electrically conductive. In some non-limiting examples, the auxiliary electrode may be formed by at least one metal and/or metal oxide. Non-limiting examples of such metals include Cu, Al, molybdenum (Mo) and/or Ag. By way of non-limiting examples, the auxiliary electrode may comprise a multi-layer metallic structure, including without limitation, one formed by Mo/Al/Mo. Non-limiting examples of such metal oxides include ITO, ZnO, IZO and/or other oxides containing In and/or Zn. In some non-limiting examples, the auxiliary electrode may comprise a multi-layer structure formed by a combination of at least one metal and at least one metal oxide, including without limitation, Ag/ITO, Mo/ITO, ITO/Ag/ITO and/or ITO/Mo/ITO. In some non-limiting examples, the auxiliary electrode comprises a plurality of such electrically conductive materials.

### Removal of Selective Coatings

In some non-limiting examples, the NIC 810 may be removed subsequent to deposition of the conductive coating 830, such that at least a part of a previously exposed layer surface 111 of an underlying material covered by the NIC 810 may become exposed once again. In some non-limiting examples, the NIC 810 may be selectively removed by etching and/or dissolving the NIC 810 and/or by employing plasma and/or solvent processing techniques that do not substantially affect or erode the conductive coating 830.

In some non-limiting examples, once an NIC 810 has been selectively deposited on a first portion of an exposed layer surface 111 of an underlying material, including without limitation, the substrate 110, a conductive coating 830 can be deposited on the exposed layer surface 111 of the underlying material, that is, on both the exposed layer surface 111 of NIC 810 where the NIC 810 has been previously deposited, as well as the exposed layer surface 111 of the substrate 110, where the NIC 810 has not been previously deposited.

Because of the nucleation-inhibiting properties of the first portion where the NIC 810 was disposed, the conductive coating 830 disposed thereon tends not to remain, resulting in a pattern of selective deposition of the conductive coating 830, that corresponds to a second portion, leaving the first portion substantially devoid of the conductive coating.

Thereafter, the NIC 810 is removed from the first portion of the exposed layer surface 111 of the substrate 110, such that the conductive coating 830 previously deposited remains on the substrate 110 and regions of the substrate 110 on which the NIC 810 had been previously deposited are now exposed or uncovered.

In some non-limiting examples, the removal of the NIC 810 may be effected by exposing the device to a solvent and/or a plasma that reacts with and/or etches away the NIC 810 without substantially impacting the conductive coating 830.

In some non-limiting examples, the TFT structure 200 and the first electrode 120 may positioned, in a cross-sectional aspect, below (sub-) pixel(s) corresponding thereto, and together with the auxiliary electrode, lie beyond a transmissive region. As a result, these components do not attenuate or impede light from being transmitted through the transmissive region. In some non-limiting examples, such arrangement allows a viewer viewing the device from a typical viewing distance to see through the device, in some non-limiting examples, when all of the (sub-) pixel(s) are not emitting, thus creating a transparent AMOLED device.

Those having ordinary skill in the relevant art will appreciate that in some non-limiting examples, the PDL(s) 440 may have a reduced thickness, including without limitation, by forming a well therein, which in some non-limiting examples is not dissimilar to the well defined for emissive region(s) 2610, to further facilitate light transmission through the transmissive region.

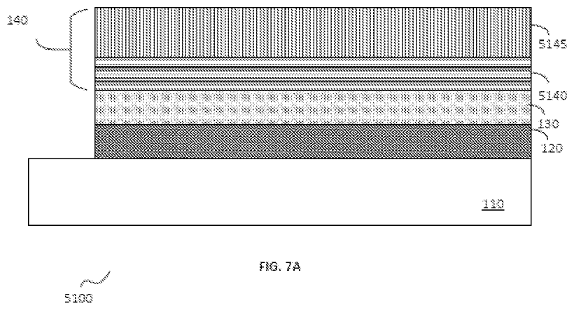

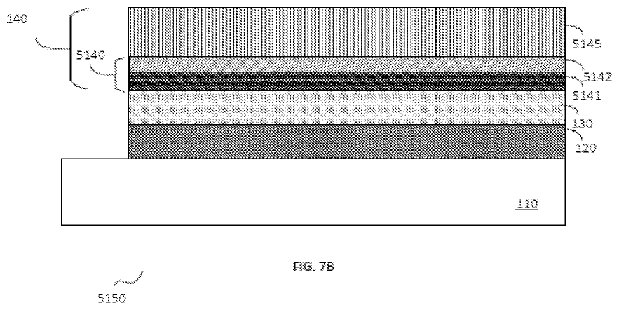

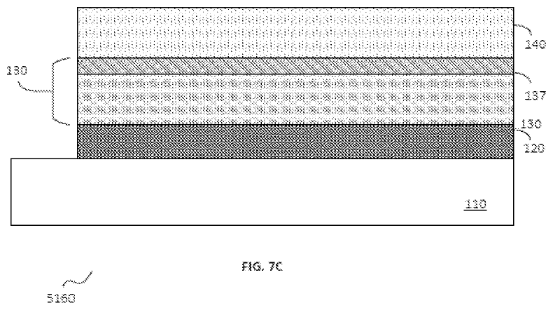

FIG. 7A illustrates a non-limiting example version, shown generally at 5100, of the device 100 shown in FIG. 1, in which the second electrode 140 comprises a lower section 5140 and an upper section 5145. The lower section 5140 may be arranged proximate and/or disposed over to an exposed layer surface 111 of one of the at least one semiconducting layers 130 and the upper section 5145 may be disposed over the lower section 5140.

In some non-limiting examples, a thickness of the lower section 5140 may be between about 1 nm and about 5 nm. By way of non-limiting example, the thickness of the lower section 5140 may be between about 2 nm and about 5 nm, and/or between about 2 nm and about 4 nm.

In some non-limiting examples, a thickness of the upper section 5145 may be between about 5 nm and about 30 nm. By way of non-limiting example, the thickness of the upper section 5145 may be between about 5 nm and about 25 nm, between about 5 nm and about 20 nm, between about 5 nm and about 18 nm, between about 7 nm and about 20 nm, between about 8 nm and about 18 nm, between about 8 nm and about 16 nm, and/or between about 10 nm and about 15 nm.

In the present disclosure, the term “fullerene” may refer generally to a material including carbon molecules. Non-limiting examples of fullerene molecules include carbon cage molecules, including without limitation, a three-dimensional skeleton that includes multiple carbon atoms that form a closed shell and which may be, without limitation, spherical and/or semi-spherical in shape. In some non-limiting examples, a fullerene molecule can be designated as Cₙ, where n is an integer corresponding to a number of carbon atoms included in a carbon skeleton of the fullerene molecule. Non-limiting examples of fullerene molecules include Cₙ, where n is in the range of 50 to 250, 60 to 84, or 60 or greater, such as, without limitation, C₆₀, C₇₀, C₇₂, C₇₄, C₇₆, C₇₈, C₈₀, C₈₂, and C₈₄, and mixtures and/or other combinations thereof. Additional non-limiting examples of fullerene molecules include carbon molecules in a tube and/or a cylindrical shape, including without limitation, single-walled carbon nanotubes and/or multi-walled carbon nanotubes.

In some non-limiting examples, the second electrode 140 comprises Yb and Mg. In some non-limiting examples, the second electrode 140 comprises a non-zero amount of Yb of up to 35 vol. % of the second electrode 140. By way of non-limiting example, the second electrode may comprise Yb in a concentration of up to about 30 vol. %, up to about 25 vol. %, up to about 20 vol. %, up to about 15 vol. %, up to about 12 vol. %, and/or up to about 10 vol. %. By way of non-limiting example, the second electrode may comprise Yb in a concentration that is between about 5 vol. % and about 30 vol. %, between about 5 vol. % and about 25 vol. %, between about 8 vol. % and about 23 vol. %, between about 8 vol. % and about 20 vol. %, between about 8 vol. % and about 18 vol. %, between about 10 vol. % and about 18 vol. %, and/or between about 10 vol. % and about 20 vol. %. In some non-limiting examples, the remainder of the second electrode 140 is substantially comprised of Mg.

In some non-limiting examples, the second electrode 140 comprises Yb, fullerene, and Mg. In some non-limiting examples, the second electrode 140 comprises a non-zero amount of fullerene of up to 15 vol. % of the second electrode 140, and a non-zero amount of Yb of up to about 25 vol. % of the second electrode 140. In some non-limiting examples, Yb and fullerene may be present in the form of ytterbium fulleride in second electrode 140. By way of non-limiting example, the second electrode 140 may comprise fullerene in a concentration of up to about 13 vol. %, up to about 11 vol. %, up to about 10 vol. %, up to about 8 vol. %, up to about 6 vol. %, and/or up to about 5 vol. %. By way of non-limiting example, the second electrode 140 may comprise fullerene in a concentration that is between about 1 vol. % and about 15 vol. %, between about 1 vol. % and about 13 vol. %, between about 1 vol. % and about 10 vol. %, between about 2 vol. % and about 8 vol. %, and/or between about 2 vol. % and about 6 vol. %. By way of non-limiting example, the second electrode may comprise Yb in a concentration of up to about 25 vol. %, up to about 20 vol. %, up to about 15 vol. %, up to about 12 vol. %, and/or up to about 10 vol. %. By way of non-limiting example, the second electrode may comprise Yb in a concentration that is between about 5 vol. % and about 25 vol. %, between about 8 vol. % and about 25 vol. %, between about 8 vol. % and about 20 vol. %, between about 8 vol. % and about 20 vol. %, between about 8 vol. % and about 18 vol. %, between about 10 vol. % and about 18 vol. %, and/or between about 10 vol. % and about 20 vol. %. In some non-limiting examples, the remainder of the second electrode 140 is substantially comprised of Mg.

In some non-limiting examples, a concentration of fullerene in the lower section 5140 may be greater than a concentration of fullerene in the upper section 5145. In some non-limiting examples, a concentration of Yb in the lower section 5140 may be greater than a concentration of Yb in the upper section 5145. In some non-limiting examples, an average concentration of fullerene in the lower section 5140 may be greater than a concentration of fullerene across the entire second electrode 140. In some non-limiting examples, an average concentration of Yb in the lower section 5140 may be greater than an average concentration of Yb across the entire second electrode 140.

In some non-limiting examples, the lower section 5140 comprises and/or substantially comprises Yb. In some non-limiting examples, a concentration of Yb in the lower section 5140 may be greater than about 50 vol. %, greater than about 60 vol. %, greater than about 70 vol. %, greater than about 75 vol. %, greater than about 80 vol. %, greater than about 90 vol. %, greater than about 95 vol. %, and/or greater than about 99 vol. %.

In some non-limiting examples, the upper section 5145 comprises Mg and Yb. In some non-limiting examples, the upper section 5145 is substantially devoid of either or both of fullerene and Yb. By way of non-limiting example, the upper section 5145 may comprise and/or substantially comprise Mg. In some non-limiting examples, the upper section 5145 may comprise a Yb-containing Mg alloy that includes a non-zero amount of Yb of up to 15 vol. %. By way of non-limiting example, a concentration of Yb in the upper section 5145 may be between about 0.1 vol. % and about 15 vol. %, between about 0.1 vol. % and about 13 vol. %, between about 0.1 vol. % and about 2 vol. %, between about 0.5 vol. % and about 2 vol. %, between about 4 vol. % and about 15 vol. %, between about 5 vol. % and about 13 vol. %, and/or between about 5 vol. % and about 10 vol. %. In some non-limiting examples, a remainder of the second electrode 140 substantially comprises Mg.

Turning now to FIG. 7B, there is shown an example version, shown generally at 5150, of the device 100, in which the lower section 5140 further comprises an interface section 5141. As illustrated, the interface section 5141 is arranged to be in physical contact with the at least one semiconductor layer 130. By way of non-limiting example, the interface section 5141 may correspond to a part of the second electrode 140 arranged at an interface between the second electrode 140 and the at least one semiconductor layer 130. Additionally, an intermediate section 5142 is shown in FIG. 7B as being arranged between the interface section 5141 and the upper section 5145.

In some non-limiting examples, the interface section 5141 may comprise ytterbium fulleride. By way of non-limiting example, a chemical state of Yb in the interface section 5141 may comprise Yb²⁺, Yb³⁺ and/or mixtures thereof. In some non-limiting examples, the ytterbium fulleride in the interface section 5141 may have a chemical formula of YbₓC_{y}, where x and y satisfy the relationships: 2≤x≤3, and 50≤y≤84. By way of non-limiting example, a thickness of the interface section 5141 may be between about 0.5 nm and about 5 nm, between about 1 nm and about 4 nm, and/or between about 1 nm and about 3 nm.

In some non-limiting examples, the intermediate section 5142 may comprise Yb. By way of non-limiting example, the intermediate section 5142 may be substantially devoid of fullerene. In some non-limiting examples, the intermediate section 5142 may comprise mg. By way of non-limiting examples, a concentration of Yb in the intermediate section 5142 may be greater than a concentration of Yb in the interface section 5141 or the upper section 5145. By way of non-limiting examples, the concentration of Yb in the intermediate section 5142 may be greater than about 40 vol. %, greater than about 50 vol. %, greater than about 60 vol. %, greater than about 70 vol. %, greater than about 75 vol. %, greater than about 80 vol. %, and/or greater than about 90 vol. %. In some non-limiting examples, the intermediate section 5142 may be substantially composed of Yb.

Turning now to FIG. 7C, there is shown an example version, shown generally at 5160, of the device 100, in which the second electrode 140 comprises a Yb-containing Mg alloy that comprises a non-zero amount of Yb of up to 15 vol. %. In some non-limiting examples, a concentration of Yb in the Yb-containing Mg alloy is between about 5 vol. % and about 15 vol. %, between about 5 vol. % and about 13 vol. %, and/or between about 5 vol. % and about 10 vol. %. In some non-limiting examples, a remainder of the Yb-containing Mg alloy substantially comprises Mg.

Without wishing to be bound by any particular theory, it may be postulated that the lower section 5140 of the second electrode 140, that comprises Yb in the example of FIG. 7A, may be omitted in at least some cases in which a concentration of Yb in the Yb-containing Mg alloy is greater than about 5 vol. %. Accordingly, in the non-limiting example of FIG. 7C, the second electrode 140 is provided by the Yb-containing Mg alloy, which is in physical contact with the at least one semiconducting layer 130, which may, in some non-limiting examples, be the ETL 137 when the EIL 139 is not present.

In a non-limiting example of FIG. 7A, Yb may be provided at an interface between the second electrode 140 and the at least one semiconducting layer 130, since the lower section 5140 of the second electrode 140 comprises Yb.

In a non-limiting example of FIG. 7C, while the lower section 5140 is not specifically provided, Yb may nevertheless be disposed at an interface between the second electrode 140 and the at least one semiconducting layer 130. Without wishing to be bound by any particular theory, it may be postulated that, when depositing the Yb-containing Mg alloy, including by co-evaporating Yb and Mg, Yb may have a higher likelihood of nucleating on an exposed layer surface 111 of the at least one semiconducting layer 130 relative to Mg. Upon some amount of Yb becoming deposited on the exposed layer surface 111 of the at least one semiconducting layer 130, a coating comprising a mixture of Mg and Yb may subsequently be deposited thereon to form the second electrode 140. Accordingly, in some non-limiting example, a concentration of Yb at or near such interface between the second electrode 140 and the at least one semiconducting layer 130 may be greater than an average concentration of Yb in the second electrode 140.

Turning now to FIG. 8, there is shown an example plan view of a transmissive (transparent) version, shown generally at 2700, of the device 100. In some non-limiting examples, the device 2700 is an AMOLED device having a plurality of pixel areas, each of which comprises a corresponding transmissive region 2620.

In some non-limiting examples, each pixel area comprises a pixel region 2610, which in turn may comprise a plurality of emissive regions 2610 each corresponding to a sub-pixel 264x. In some non-limiting examples, the sub-pixels 264x may correspond to, respectively, R(ed) sub-pixels 2641, G(reen) sub-pixels 2642 and/or B(lue) sub-pixels 2643.

In some non-limiting examples, each transmissive region 2620 is substantially transparent and allows light to pass through the entirety of a cross-sectional aspect thereof. In some non-limiting examples, each pixel area may also comprise an intervening region arranged between the pixel region 2610 and the transmissive region 2620.

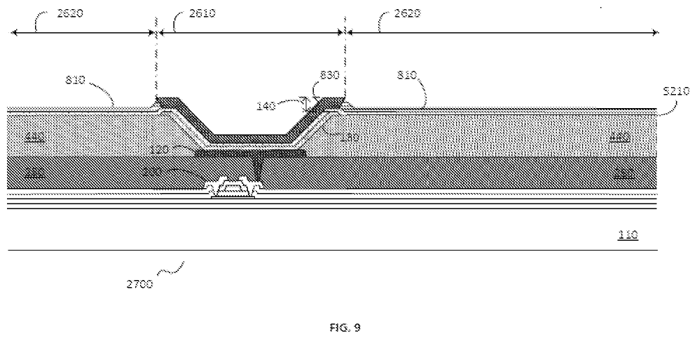

Turning now to FIG. 9, there is shown an example cross-sectional view of the device 2700, taken along line 27B-27B in FIG. 8. In the figure, the device 2700 is shown as comprising a substrate 110, a TFT structure 200 corresponding to and for driving each sub-pixel 264x positioned substantially thereunder, a TFT insulating layer 280 and a first electrode 120, which in some non-limiting examples, may be an anode, formed on a surface of the TFT insulating layer 280 and electrically coupled to the corresponding TFT structure 200. PDL(s) 440 are formed in non-emissive regions 2620 over the TFT insulating layer 280, to define emissive region(s) 2610 also corresponding to each sub-pixel 264x, over the first electrode 120 corresponding thereto. The PDL(s) 440 cover edges of the first electrode 120.

In some non-limiting examples, at least one semiconducting layer 130 is deposited over exposed region(s) of the first electrode 120 and, in some non-limiting examples, at least parts of the surrounding PDLs 440.

An interface coating 5210 is then deposited to be arranged in both the pixel region 2610 and the transmissive region 2620. By way of non-limiting example, the interface coating 5210 may be provided as a continuous closed layer or structure extending substantially laterally to cover such regions.

An NIC 810 is deposited to cover portions of the device 2700 corresponding to the transmissive region 2620.

The entire exposed layer surface 111 of the device 2700 is exposed to a vapor flux of a conductive coating material 831, such that the conductive coating 830 is selectively deposited substantially only on a portion of the exposed layer surface 111 that is substantially devoid of the NIC 810, namely that portion corresponding to the pixel region 2610, which is substantially devoid of a closed coating layer of the NIC 810. In some non-limiting examples, the conductive coating material 831 may be deposited onto the surface of the NIC 810 as a discontinuous coating that manifests as a plurality of discontinuous clusters thereon.

Without wishing to be bound to any particular theory, it may be postulated that, at least in some non-limiting examples, materials such as Yb may nucleate on the exposed layer surface 111 of the NIC 810 under some conditions. Continued incidence of evaporated flux of the conductive coating material 831 onto such surface may cause the discontinuous coating, for example in the form of discontinuous islands and/or clusters, of the material to be deposited onto such exposed layer surface 111. By way of non-limiting examples, such discontinuous coating may comprise Mg and/or Yb.

However, it has now been found that a light transmittance may not be substantially affected by the presence of such discontinuous coating. By way of non-limiting example, an average thickness of such discontinuous coating formed in such manner, may be substantially thin, including without limitation, less than about 2 nm, less than about 1 nm, and/or less than about 0.5 nm, such that it may allow transmission of light therethrough without substantial attenuation. By way of non-limiting example, a thickness of the conductive coating material 831 arranged in the transmissive region 2620 may be less than about 20%, less than about 15%, less than about 10%, less than about 5%, less than about 3%, and/or less than about 1%of a thickness of the conductive coating 830 in the pixel region 2610.

Thus, the conductive coating 830, together with the interface coating 5210, may form the second electrode 140, which may, in some non-limiting examples be a cathode, in some non-limiting examples of a top-emission device, including as described above in respect of FIGS. 7A and/or 7B.

In some non-limiting examples, the interface coating 5210 may be dispensed with, such that the conductive coating 830 is in physical contact with the at least one semiconducting layer 130. In such non-limiting examples, Yb may nevertheless be disposed at an interface between the at least one semiconducting layer 130 and the conductive coating 830, as discussed previously.

In some non-limiting examples, the conductive coating 830 comprises Mg and Yb. In some non-limiting examples, the conductive coating 830 comprises a Yb-containing Mg alloy. In some non-limiting examples, an average concentration of Yb may be lower than an average concentration of Mg in the Yb-containing Mg alloy.

In some non-limiting examples, the Yb-containing Mg alloy may be formed by co-evaporating Mg and Yb from separate evaporation sources. In some non-limiting examples, the Yb-containing Mg alloy of the conductive coating may be formed by evaporating a single source material comprising both Yb and Mg. By way of non-limiting example, such single source material may be formed as a single monolithic or continuous structure, which may then be evaporated by any of the various deposition methodologies described herein, including without limitation, by a thermal evaporation method, to form the Yb-containing Mg alloy.

It has now been found, somewhat surprisingly, that a thin, transmissive conductive coating 830, formed by including a Yb-containing Mg alloy, may exhibit favourable properties relative to similar coatings formed by substantially pure Mg and/or a bi-layer structure of Yb/Mg. By way of non-limiting example, devices fabricated using a Yb-containing Mg alloy as a transmissive cathode have been found to exhibit improved thermal stability when subjected for a prolonged period of time to elevated temperatures. contaminants or impurities that may be found in the conductive coating 830 used to form the second electrode 140 may comprise a relatively small fraction of an overall composition of the second electrode 140 and may not substantially affect properties thereof.

In some non-limiting examples, the interface coating 5210 is in physical contact with the at least one semiconducting layer 130 in the pixel region 2610. In some non-limiting examples, the interface coating 5210 is also in physical contact with the NIC 810 in the transmissive region 2620. In some non-limiting examples, the NIC 810 may be deposited after deposition of the interface coating 5210, such that it is deposited over the interface coating 5210.

In some non-limiting examples, the second electrode 140 is substantially devoid of any TCO. In some non-limiting examples, the device 2700 does not have a layer of TCO adjacent to and/or in physical contact with the second electrode 140.

In some non-limiting examples, Mg may constitute at least a majority, or more than a majority, of the second electrode 140, in terms of percentage by volume. By way of non-limiting example, Mg may constitute at least about 50 vol. % of the second electrode 140, such as at least about 55 vol. %, at least about 60 vol. %, at least about 65 vol. %, at least about 70 vol. %, at least about 75 vol. %, at least about 80 vol. %, at least about 90 vol. %, and/or at least about 95 vol. % of the second electrode 140. In some non-limiting examples, the second electrode 140 may comprise a non-zero amount of Yb, and/or in some non-limiting examples, a non-zero amount of a fullerene, and a remainder of the second electrode 140 may comprise Mg.

In some non-limiting examples, the interface coating 5210 comprises an alkali metal. In some non-limiting examples, the interface coating 5210 comprises Yb. In some non-limiting examples, the interface coating 5210 also comprises a fullerene. In some non-limiting examples, the interface coating 5210 comprises an alkali fulleride. By way of non-limiting example, the interface coating 5210 comprises ytterbium fulleride. By way of non-limiting example, a chemical state of Yb in the interface coating 5210 may comprise Yb²⁺, Yb³⁺ and/or mixtures thereof. In some non-limiting examples, the ytterbium fulleride has a chemical formula of YbₓC_{y}, where x and y satisfy the relationships: 2≤x≤3, and 50≤y≤84.

By way of non-limiting example, a thickness of the interface coating 5210 may be between about 0.5 nm and about 5 nm, between about 1 nm and about 4 nm, and/or between about 1 nm and about 3 nm. In some non-limiting examples, particularly in the transmissive region 2620, the interface coating 5210 may be substantially devoid of Mg. By way of non-limiting example, the interface coating 5210 may substantially comprise Yb. Without wishing to be bound by any particular theory, it may be postulated that Mg in the conductive coating 810 may migrate and/or become doped into the interface coating 5210 in the pixel region 2610.

In some non-limiting examples, the conductive coating 830 comprises Mg. In some non-limiting examples, the conductive coating 830 is substantially devoid of fullerene and/or Yb. By way of non-limiting example, the conductive coating 830 may be comprised substantially of Mg. In some non-limiting examples, contaminants or impurities that may be found in the conductive coating 830 used to form the second electrode 140 may comprise a relatively small fraction of an overall composition of the second electrode 140 and may not substantially affect properties thereof.

In some non-limiting examples, a thickness of the conductive coating 830 may be between about 5 nm and about 30 nm. By way of non-limiting example, a thickness of the conductive coating 830 may be between about 5 nm and about 25 nm, between about 5 nm and about 20 nm, between about 5 nm and about 18 nm, between about 7 nm and about 20 nm, between about 8 nm and about 18 nm, between about 8 nm and about 16 nm, and/or between about 10 nm and about 15 nm.

In some non-limiting examples, the interface coating 5210 may be substantially omitted from the transmissive region 2620. By way of non-limiting example, the interface coating 5210 may be selectively deposited to avoid the transmissive region 2620 using a mask.

However, it has now been discovered, somewhat surprisingly, that the presence of the interface coating 5210 in the transmissive region 2620 may not substantially attenuate and/or affect the transmission of light through the device 2700 within the transmissive region 2620. As a result, in some non-limiting examples, such as is shown in FIG. 9, the interface coating 5210 may be disposed within the transmissive region 2620.

The various materials and/or coatings described herein, including without limitation, fullerene, Yb and/or Mg may be deposited by any of the various deposition methodologies described herein, including without limitation, by a thermal evaporation method.

While the foregoing has been described with reference to an example top-emission OLED device having a transmissive second electrode 140 as a cathode, in some non-limiting examples, a transmissive first electrode 120 that may, in some non-limiting examples, be an anode, may be provided instead of such second electrode 140 and/or in addition thereto. By way of non-limiting example, the transmissive electrode 120, 140, may be used as a transmissive anode in an inverted OLED, wherein the anode is a common electrode 120, 140, of an OLED device and/or any other electronic device.

### EXAMPLES

The following examples are for illustrative purposes only and are not intended to limit the generality of the present disclosure in any fashion.

### Example 1

In order to characterize performance and/or stability of the device 2700 using various configurations of the transmissive electrode 120, 140, a series of example top-emission OLED devices were fabricated using identical configurations of the first electrode 120 acting as an anode and the at least one semiconductor layer 130, while the example devices were then encapsulated and baked at 100° C. inside an N₂ glove box for 500 hours. The operating voltage of each example device was measured before and after baking to determine a value for ΔV. The second electrode 140 structure used in each example device, along with the measured ΔV values are summarized in the table below:

| Sample | | |
|---|---|---|
| # | Cathode Structure | ΔV |
| 1 | Yb (2 nm)/Mg (8 nm) | 0.46 |
| 2 | Yb (2 nm)/Mg (10 nm) | 0.26 |
| 3 | Yb (2 nm)/Mg (12 nm) | 0.16 |
| 4 | Yb (2 nm)/Mg (16 nm) | 0.18 |
| 5 | Yb (2 nm)/Mg (18 nm) | 0.16 |
| 6 | Yb (2 nm)/Mg:Ag (1:10, 10 nm) | 0.26 |
| 7 | Yb (2 nm)/Mg:Ag (1:10, 14 nm) | 0.25 |
| 8 | C₆₀ (1 nm)/Yb (2 nm)/Mg (8 nm) | 0.31 |
| 9 | C₆₀ (1 nm)/Yb (2 nm)/Mg (10 nm) | 0.11 |
| 10 | C₆₀ (1 nm)/Yb (2 nm)/Mg (12 nm) | 0.07 |
| 11 | C₆₀ (1 nm)/Yb (2 nm)/Mg (16 nm) | 0.08 |
| 12 | C₆₀ (1 nm)/Yb (2 nm)/Mg (18 nm) | 0.07 |

From the foregoing, it was found, somewhat surprisingly, that introducing a 1 nm thick layer of a fullerene (C₆₀) enhanced the device stability by reducing the ΔV value. By way of non-limiting example, such effects may be observed by comparing the results of Examples 1 through 5 against the corresponding results of Examples 8 through 12.

Those having ordinary skill in the relevant art will appreciate that experimental results and measurement values recorded in various examples may include a certain amount of error, due to, without limitation, inaccuracies, variations and/or bias in measurements, random and/or systematic errors in measurements, detection limits of tools and/or equipment used in conducting measurement, defects and/or inconsistencies in the examples used for measurements, a sample size and/or sampling error. By way of non-limiting example, the fullerene and/or Yb composition may vary by up to ±3 vol. %, ±2 vol. %, ±1 vol. %, ±0.5 vol. %, and/or ±0.1 vol. % from a recorded value in certain of the examples. In some non-limiting examples, a light transmittance, absorption and/or reflectivity may vary by up to about ±10%, ±8%, ±5%, ±3%, ±1%, ±0.5%, and/or ±0.1% from a recorded value in certain of the examples. In some non-limiting examples, a sheet resistance may vary by up to about ±10 ohm/sq, ±5 ohm/sq, ±1 ohm/sq, ±0.5 ohm/sq, and/or ±0.1 ohm/sq from a recorded value in certain of the examples. In some non-limiting examples, a thickness of the second electrode 140 may vary by up to about ±30 nm, ±15 nm, ±10 nm, ±8 nm, ±5 nm, and/or ±3 nm from a recorded value in certain of the examples. In some non-limiting examples, other reported values may vary by up to about ±10%, ±5%, ±3%, ±1%, ±0.5%, and/or ±0.1% of such numerical value.

In some non-limiting examples, reference has been made to coatings of various thicknesses and/or compositions. Those having ordinary skill in the relevant art will appreciate that the composition of such coating may be determined based on relative amounts of fullerene, Yb and/or Mg used to form such coating. By way of non-limiting example, in a coating formed by thermal evaporation, it may be typical to monitor a mass of the material(s) deposited and thus, an approximate thickness of the coating based on a reading from a quartz crystal monitor (QCM) system. By way of non-limiting example, a composition formed by thermally evaporating fullerene, Yb and/or Mg may be determined based on a QCM reading of a relative thickness and/or volume of each component deposited in the process of forming such coating.

As used herein, the term “size” refers to a characteristic dimension of an object. By way of non-limiting example, a size of an object that is substantially spherical and/or circular may refer to a diameter of such object. By way of non-limiting example, a size of an object that is non-spherical and/or non-circular may refer to a largest dimension of such object. By way of non-limiting example, a size of an ellipsoidal object may refer to a major axis thereof. When referring to a set of objects as having a particular size, it may be understood that the objects in such set may have individual sizes that are distributed about the particular size. Thus, as used herein, a size specified for a set of objects may, in some non-limiting examples, refer to a typical size and/or a distribution of sizes, such as, without limitation, an average size, a median size and/or a peak size.

Accordingly, in some non-limiting examples, amounts, ratios and/or other numerical values may be presented herein in a range format. Those having ordinary skill in the relevant art will appreciate that such range formats are used for convenience and/or brevity, and should be understood flexibly to include not only numerical values explicitly specified as a range limit, but also all individual numerical values and/or sub-ranges encompassed within such range, as if numerical value and/or sub-range had been explicitly specified.

Where features or aspects of the present disclosure are described in terms of Markush groups, it will be appreciated by those having ordinary skill in the relevant art that the present disclosure is also thereby described in terms of any individual member of sub-group of members of such Markush group.

### Terminology

References in the singular form include the plural and vice versa, unless otherwise noted.

As used herein, relational terms, such as “first” and “second”, and numbering devices such as “a”, “b” and the like, may be used solely to distinguish one entity or element from another entity or element, without necessarily requiring or implying any physical or logical relationship or order between such entities or elements.

The terms “including” and “comprising” are used expansively and in an open-ended fashion, and thus should be interpreted to mean “including, but not limited to”. The terms “example” and “exemplary” are used simply to identify instances for illustrative purposes and should not be interpreted as limiting the scope of the invention to the stated instances. In particular, the term “exemplary” should not be interpreted to denote or confer any laudatory, beneficial or other quality to the expression with which it is used, whether in terms of design, performance or otherwise.

The terms “couple” and “communicate” in any form are intended to mean either a direct connection or indirect connection through some interface, device, intermediate component or connection, whether optically, electrically, mechanically, chemically, or otherwise.

The terms “on” or “over” when used in reference to a first component relative to another component, and/or “covering” or which “covers” another component, may encompass situations where the first component is direct on (including without limitation, in physical contact with) the other component, as well as cases where one or more intervening components are positioned between the first component and the other component.

Directional terms such as “upward”, “downward”, “left” and “right” are used to refer to directions in the drawings to which reference is made unless otherwise stated. Similarly, words such as “inward” and “outward” are used to refer to directions toward and away from, respectively, the geometric center of the device, area or volume or designated parts thereof. Moreover, all dimensions described herein are intended solely to be by way of example of purposes of illustrating certain embodiments and are not intended to limit the scope of the disclosure to any embodiments that may depart from such dimensions as may be specified.

As used herein, the terms “substantially”, “substantial”, “approximately” and/or “about” are used to denote and account for small variations. When used in conjunction with an event or circumstance, such terms can refer to instances in which the event or circumstance occurs precisely, as well as instances in which the event or circumstance occurs to a close approximation. By way of non-limiting example, when used in conjunction with a numerical value, such terms may refer to a range of variation of less than or equal to ±10% of such numerical value, such as less than or equal to ±5%, less than or equal to ±4%, less than or equal to ±3%, less than or equal to ±2%, less than or equal to ±1%, less than or equal to ±0.5%, less than or equal to ±0.1%, and/or less than equal to ±0.05%.

As used herein, the phrase “consisting substantially of” will be understood to include those elements specifically recited and any additional elements that do not materially affect the basic and novel characteristics of the described technology, while the phrase “consisting of” without the use of any modifier, excludes any element not specifically recited.

As will be understood by those having ordinary skill in the relevant art, for any and all purposes, particularly in terms of providing a written description, all ranges disclosed herein also encompass any and all possible sub-ranges and/or combinations of sub-ranges thereof. Any listed range may be easily recognized as sufficiently describing and/or enabling the same range being broken down at least into equal fractions thereof, including without limitation, halves, thirds, quarters, fifths, tenths etc. As a non-limiting example, each range discussed herein may be readily be broken down into a lower third, middle third and/or upper third, etc.

As will also be understood by those having ordinary skill in the relevant art, all language and/or terminology such as “up to”, “at least”, “greater than”, “less than”, and the like, may include and/or refer the recited range(s) and may also refer to ranges that may be subsequently broken down into sub-ranges as discussed herein.

As will be understood by those having ordinary skill in the relevant art, a range includes each individual member of the recited range.

### General

The purpose of the Abstract is to enable the relevant patent office or the public generally, and specifically, persons of ordinary skill in the art who are not familiar with patent or legal terms or phraseology, to quickly determine from a cursory inspection, the nature of the technical disclosure. The Abstract is neither intended to define the scope of this disclosure, nor is it intended to be limiting as to the scope of this disclosure in any way.

The structure, manufacture and use of the presently disclosed examples have been discussed above. The specific examples discussed are merely illustrative of specific ways to make and use the concepts disclosed herein, and do not limit the scope of the present disclosure. Rather, the general principles set forth herein are considered to be merely illustrative of the scope of the present disclosure.

It should be appreciated that the present disclosure, which is described by the claims and not by the implementation details provided, and which can be modified by varying, omitting, adding or replacing and/or in the absence of any element(s) and/or limitation(s) with alternatives and/or equivalent functional elements, whether or not specifically disclosed herein, will be apparent to those having ordinary skill in the relevant art, may be made to the examples disclosed herein, and may provide many applicable inventive concepts that may be embodied in a wide variety of specific contexts, without straying from the present disclosure.

In particular, features, techniques, systems, sub-systems and methods described and illustrated in one or more of the above-described examples, whether or not described an illustrated as discrete or separate, may be combined or integrated in another system without departing from the scope of the present disclosure, to create alternative examples comprised of a combination or sub-combination of features that may not be explicitly described above, or certain features may be omitted, or not implemented. Features suitable for such combinations and sub-combinations would be readily apparent to persons skilled in the art upon review of the present application as a whole. Other examples of changes, substitutions, and alterations are easily ascertainable and could be made without departing from the spirit and scope disclosed herein.

All statements herein reciting principles, aspects and examples of the disclosure, as well as specific examples thereof, are intended to encompass both structural and functional equivalents thereof and to cover and embrace all suitable changes in technology. Additionally, it is intended that such equivalents include both currently-known equivalents as well as equivalents developed in the future, i.e., any elements developed that perform the same function, regardless of structure.

Accordingly, the specification and the examples disclosed therein are to be considered illustrative only, with a true scope of the disclosure being disclosed by the following numbered claims:

1. An opto-electronic device having a plurality of layers, comprising:
a first electrode;
a second electrode; and
at least one semiconducting layer between the first and second electrodes;
wherein the second electrode comprises ytterbium (Yb) and magnesium (Mg).

2. The opto-electronic device of claim 1, wherein a concentration of the Yb in the second electrode comprises a non-zero amount of up to 35 vol. %.

3. The opto-electronic device of claim 1, wherein a thickness of the second electrode is between about 6 nm and about 35 nm.

4. The opto-electronic device of claim 1, wherein the second electrode comprises a lower section and an upper section, wherein the lower section is between the upper section and the at least one semiconducting layer and proximate to the at least one semiconducting layer.

5. The opto-electronic device of claim 4, wherein the lower section is substantially comprised of Yb.

6. The opto-electronic device of claim 4, wherein the upper section comprises a Yb-containing Mg alloy wherein a concentration of the Yb therein comprises a non-zero amount of up to 10 vol. % of the upper section.

7. The opto-electronic device of any of claim 4, wherein a concentration of the Yb in the lower section exceeds a concentration of the Yb in the upper section.

8. The opto-electronic device of any of claim 4, wherein a thickness of the lower section is between about 1 nm and about 5 nm.

9. The opto-electronic device of any of claim 4, wherein a thickness of the upper section is between about 5 nm and about 30 nm.

10. The opto-electronic device of any of claim 4, wherein the upper section is substantially devoid of Yb.

11. The opto-electronic device of any of claim 4, wherein the upper section is comprised substantially of Mg.

12. The opto-electronic device of claim 1, wherein the second electrode further comprises a fullerene.

13. The opto-electronic device of claim 12, wherein a concentration of the fullerene in the second electrode comprises a non-zero amount of up to 15 vol. %.

14. The opto-electronic device of claim 12, wherein the second electrode comprises a lower section and an upper section, wherein the lower section is between the upper section and the at least one semiconducting layer and proximate to the at least one semiconducting layer.

15. The opto-electronic device of claim 14, wherein a concentration of fullerene in the lower section exceeds a concentration of the fullerene in the upper section.

16. The opto-electronic device of claim 14, wherein the upper section is substantially devoid of the fullerene.

17. The opto-electronic device of any of claim 4, wherein the lower section further comprises an interface section arranged to be in physical contact with the at least one semiconducting layer.

18. The opto-electronic device of claim 17, wherein a thickness of the interface section is between about 1 nm and about 5 nm.

19. The opto-electronic device of claim 17, wherein the interface section further comprises Mg.

20. The opto-electronic device of claim 17, wherein the interface section comprises ytterbium fulleride.

21. The opto-electronic device of claim 17, wherein a chemical state of Yb in the interface section comprises at least one of Yb²⁺ and Yb³⁺.

22. The opto-electronic device of claim 20, wherein the ytterbium fulleride in the interface section has a chemical formula YbₓC_{y}, wherein 2≤x≤3 and 50≤y≤84.

23. The opto-electronic device of claim 12, wherein the fullerene comprises at least one of Cₙ, where 50≤n≤250.

24. The opto-electronic device of claim 23, wherein n is selected from at least one of 60, 70, 72, 75, 76, 78, 80, 82, 84 and any combination of any of these.

25. An opto-electronic device having a plurality of layers, comprising:
a pixel region in a first portion of a lateral aspect thereof;
a light transmissive region in a second portion of a lateral aspect thereof;
a first electrode disposed in the pixel region;
an interface coating extending across the pixel region and the light transmissive region, the interface coating comprising Yb;
at least one semiconducting layer between the first electrode and the interface coating;
a nucleation inhibiting coating (NIC) disposed over the interface coating in the light transmissive region; and
a conductive coating disposed over the interface coating in the pixel region;
wherein a surface of the NIC in the light transmissive region is substantially devoid of a closed coating film of the conductive coating.

26. The opto-electronic device of claim 25, wherein the interface coating is in physical contact with the at least one semiconducting layer in the pixel region.

27. The opto-electronic device of claim 25, wherein the interface coating is in physical contact with the conductive coating in the pixel region.

28. The opto-electronic device of claim 25, wherein the interface coating is in physical contact with the NIC in the light transmissive region.

29. The opto-electronic device of claim 25, further comprising a second electrode in the pixel region comprising the interface coating and the conductive coating.

30. The opto-electronic device of claim 25, wherein the interface coating further comprises a fullerene.

31. The opto-electronic device of claim 25, wherein the fullerene comprises at least one of Cₙ, where 50≤n≤250.

32. The opto-electronic device of claim 31, wherein n is selected from at least one of 60, 70, 72, 75, 76, 78, 80, 82, 84 and any combination of any of these.

33. The opto-electronic device of claim 25, wherein at least one discontinuous cluster of a material for forming the conductive coating is arranged on a surface of the NIC in the transmissive region.

34. The opto-electronic device of claim 33, wherein light transmitted through the transmissive region passes substantially through the at least one discontinuous cluster thereon.

35. The opto-electronic device of claim 34, wherein a thickness of the material for forming the conductive coating on the surface of the NIC is less than about 10% of a thickness of the conductive coating in the pixel region.

36. An opto-electronic device having a plurality of layers, comprising:
a pixel region in a first portion of a lateral aspect thereof;
a light transmissive region in a second portion of a lateral aspect thereof;
a first electrode disposed in the pixel region;
at least one semiconducting layer disposed over the first electrode;
a nucleation inhibiting coating (NIC) disposed over the at least one semiconducting layer in the light transmissive region; and
a conductive coating disposed over the at least one semiconducting layer in the pixel region, the conductive coating comprising a ytterbium-containing magnesium alloy wherein a concentration of the ytterbium therein comprises a non-zero amount of up to 15 vol. % of the conductive coating;
wherein a surface of the NIC in the light transmissive region is substantially devoid of a closed coating film of the conductive coating.
